(19) United States
(12) Patent Application Publication
(10) Pub. No.: US 2026/0262384 A1
(43) Pub. Date: Sep. 3, 2026

(54) DISPLAY SUBSTRATE AND MANUFACTURING METHOD THEREOF, DISPLAY DEVICE

(71) Applicants: Beijing BOE Technology Development Co., Ltd., Beijing (CN); BOE Technology Group Co., Ltd., Beijing (CN)

(72) Inventors: Chunyang WANG, Beijing (CN); Mingche HSIEH, Beijing (CN)

(21) Appl. No.: 18/837,933

(22) PCT Filed: Nov. 7, 2023
(86) PCT No.: PCT/CN2023/130296

§ 371 Date: Aug. 13, 2024

(51) Int. Cl. H10K 59/122; H10K 59/12; H10K 59/131

(52) U.S. Cl. CPC H10K 59/122; H10K 59/1201; H10K 59/131

(57) ABSTRACT

A display substrate and a manufacturing method and display device thereof. The display substrate includes: a substrate, a plurality of pixel units and a wire. A plurality of pixel units are on the substrate. Each pixel unit includes a first sub-pixel and a second sub-pixel. The first sub-pixel and the second sub-pixel include a common film layer. For each pixel unit, the orthographic projection of the first sub-pixel on the substrate and the orthographic projection of the second sub-pixel on the substrate are relatively arranged on both sides of the wire. At least part of the common film is broken in the area overlapping with the wire and separated from the wire to form a first opening.

### CROSS-REFERENCE TO RELATED APPLICATIONS

This application is a national phase entry under 35 U.S. C § 371 of International Application No. PCT/CN2023/130296, filed on Nov. 7, 2023, which is hereby incorporated by reference in its entirety.

### TECHNICAL FIELD

The present disclosure relates to the field of display technology, in particular to a display substrate and a manufacturing method thereof, and a display device.

### BACKGROUND

With the gradual increase in the importance of personal privacy, more and more users have a strong demand for the anti-peeping function of electronic products such as mobile phones. At present, the anti-peeping film attached to the display screen of electronic products can play the role of anti-peeping, but cannot switch between the anti-peeping function and the sharing function. For example, when the user needs to share screen information with others, it is difficult to share a wide range because the viewing angle of the external anti-peeping film is narrow.

By dividing the pixel units into anti-peeping sub-pixels and display sub-pixels, only the anti-peeping sub-pixels are lit up in the anti-peeping mode for image display, so as to realize the anti-peeping function. In the normal mode, the anti-peeping sub-pixels and the display sub-pixels are lit at the same time for image display, so as to realize the sharing function. For example, when above technical means is applied to the display substrate of organic light emitting diode (OLED), because part of the film layer that forms the anti-peeping sub-pixels and the part of the film that forms the display sub-pixels are made on the whole side during the production and communicate with each other to form a common film, the current crosstalk between the anti-peeing sub-pixels and the display sub-pixels is easy to occur through the common film and affect the anti-peeping effect.

### SUMMARY

The disclosure provides a display substrate and a manufacturing method thereof, a display device, for solving the current crosstalk problem between the anti-peeping sub-pixels and the display sub-pixels caused by a common film.

The first aspect of the present disclosure provides a display substrate, including:
a substrate;
a plurality of pixel units located on the substrate; each of the pixel units includes a first sub-pixel and a second sub-pixel; the first sub-pixel and the second sub-pixel include a common film layer;
a wire, for at least a part of the pixel units, an orthographic projection of the first sub-pixel on the substrate and an orthographic projection of the second sub-pixel on the substrate, are relatively arranged on both sides of the wire; at least a part of the common film layer is broken in an area overlapping with the wire and is spaced apart from the wire to form a first opening.

The display substrate further includes:
a pixel definition layer located on a side of the substrate; the pixel definition layer is provided with a first pixel opening and a second pixel opening; the first pixel opening and the second pixel opening pass through the pixel definition layer along a thickness direction of the pixel definition layer; the common film layer is located on a side away from the substrate, of the pixel definition layer, and is partly located between the first pixel opening and the second pixel opening;
the first sub-pixel and the second sub-pixel are separated by a part of the pixel definition layer located between the first pixel opening and the second pixel opening; for each of the pixel units, an orthographic projection of the first pixel opening on the substrate and an orthographic projection of the second pixel opening on the substrate are located on both sides of an orthotropic projection of the wire on the substrate.

In the display substrate of the present disclosure, the wire is located on the side away from the substrate, of the pixel defining layer.

In the display substrate of the present disclosure, the wire is located between the common film layer and the pixel definition layer.

In the display substrate of the present disclosure, the wire is located on a side away from the common film layer, of the pixel definition layer;
the pixel definition layer is further provided with a second opening; the second opening passes through the pixel definition layer along the thickness direction of the pixel definition layer, and exposes the wire; at least a part of the common film layer is broken at a position of the second opening to form the first opening.

The display substrate further includes a first electrode and a second electrode located between the pixel definition layer and the substrate; the first electrode and the second electrode are spaced apart; the first electrode is used for forming the first sub-pixel, and the second electrode is used for forming the second sub-pixel;
for each of the pixel units, an orthotropic projection of the first electrode on the substrate and an orthographic projection of the second electrode on the substrate are located on both sides of the orthographic projection of the wire on the substrate.

In the display substrate of the present disclosure, the wire is located in a conductive film layer same as a layer where the first electrode and the second electrode are; the wire, the first electrode and the second electrode are separated by the pixel definition layer.

The display substrate further includes a thermal insulation layer located on the side away from the common film layer, of the wire; an orthographic projection of the wire on the substrate is within an orthographic projection of the thermal insulation layer on the substrate.

In the display substrate of the present disclosure, the orthographic projection of the wire on the substrate and the orthographic projection of the thermal insulation layer on the substrate completely coincide.

In the display substrate of the present disclosure, the wire includes an input terminal and an output terminal; the input terminal and the output terminal are used for loading a voltage on the wire to form a current.

The display substrate further includes a pixel region and a non-pixel region; the pixel units are located within the pixel region; the input terminal and the output terminal of the wire are located in the non-pixel region.

In the display substrate of the present disclosure, the wire continuously passes through each of the pixel units within the pixel region, so that the first sub-pixel and the second sub-pixel in each of the pixel units are positioned on both sides of the wire.

In the display substrate of the present disclosure, the wire includes a first connecting portion and a second connecting portion; the first connecting portion and the second connecting portion are relatively arranged on both sides of the pixel region and extend along a first direction; wherein the first connecting portion is connected with the input terminal, and the second connecting portion is connected with the output terminal;
the wire further includes a plurality of separating portions extending in a second direction and arranging in the first direction; one end of each of the separating portions is connected with the first connecting portion, and the other end of each of the separating portions is connected with the second connecting portion; each of the separating portions passes through the pixel units located in a same row in the second direction, so that the first sub-pixel and the second sub-pixel in each of the pixel units are located on both sides of the wire.

In the display substrate of the present disclosure, a part of the common film layer is located between two adjacent pixel units;
at least a part of the pixel units are relatively arranged on both sides of the wire.

In the display substrate of the present disclosure, in a same pixel unit, a luminous color of the first sub-pixel is the same as a luminous color of the second sub-pixel.

In the display substrate of the present disclosure, the first sub-pixel and the second sub-pixel are organic light-emitting diodes;
the organic light-emitting diode includes:
a first electrode layer located on a side of the substrate;
a first functional layer located on a side away from the substrate, of the first electrode layer; the first functional layer includes at least one film layer;
an organic light-emitting layer located on a side away from the first electrode layer, of the first functional layer;
a second functional layer located on a side away from the first functional layer, of the organic light-emitting layer; the second functional layer includes at least one film layer;
a second electrode layer located on a side away from the organic light-emitting layer, of the second functional layer;
the common film layer includes at least one of the first functional layer, the second functional layer or the second electrode layer.

In the display substrate of the present disclosure, the first functional layer includes a hole transport layer and a hole injection layer, the hole transport layer and the hole injection layer are stacked in a direction away from the organic light-emitting layer; the second functional layer includes an electron transport layer and an electron injection layer, the electron transport layer and an electron injection layer are stacked in the direction away from the organic light-emitting layer.

The second aspect of the present disclosure provides a display device including the display substrate of any one of above embodiments.

The third aspect of the present disclosure provides a method for manufacturing a display substrate, including:
forming a first electrode and a second electrode spaced apart from each other on a side of a substrate; the first electrode is used for forming a first sub-pixel, and the second electrode is used for forming a second sub-pixel;
forming a pixel definition layer on a side away from the substrate, of the first electrode and the second electrode; the pixel definition layer is provided with a first pixel opening for exposing the first electrode and a second pixel opening for exposing the second electrode;
forming a wire on a side away from the substrate, of the pixel definition layer, so that an orthographic projection of at least a part of the first pixel opening on the substrate and an orthographic projection of at least a part of the second pixel opening on the substrate are relatively arranged on both sides of the wire;
manufacturing the first sub-pixel and the second sub-pixel respectively in the first pixel opening and the second pixel opening; the first sub-pixel and the second sub-pixel include a common film layer, and the common film layer covers the pixel definition layer and the wire between the first pixel opening and the second pixel opening;
applying a voltage to the wire so that the wire is heated to ablate at least a part of the common film layer in an area overlapping with the wire to form the first opening.

The fourth aspect of the present disclosure provides a method for manufacturing a display substrate, including:
forming a first electrode, a second electrode and a wire which are spaced from each other on a side of a substrate; at least a part of the first electrode and at least a part of the second electrode are relatively arranged on both sides of the wire; the first electrode is used for forming a first sub-pixel, and the second electrode is used for forming a second sub-pixel;
forming a pixel definition layer on a side away from the substrate, of the first electrode and the second electrode; the pixel definition layer is provided with a first pixel opening for exposing the first electrode, a second pixel opening for exposing the second electrode and a second opening for exposing the wire; the second opening is between the first pixel opening and the second pixel opening;
manufacturing the first sub-pixel and the second sub-pixel respectively in the first pixel opening and the second pixel opening; the first sub-pixel and the second sub-pixel include a common film layer, the common film layer covers the pixel definition layer between the first pixel opening and the second pixel opening, and the wire in the second opening;
applying a voltage to the wire so that the wire is heated to ablate at least a part of the common film layer in an area overlapping with the wire to form the first opening.

The beneficial effects of this disclosure are as follows.

The disclosure provides a display substrate and a manufacturing method and a display device, and the display substrate includes: a substrate, a plurality of pixel units and wires. Multiple pixel units are located on the substrate. Each pixel unit includes a first sub-pixel and a second sub-pixel. The first and second sub-pixels include a common film layer. For each pixel unit, the orthographic projection of the first sub-pixel on the substrate and the orthotropic projection of the second sub-pixel on the substrate are arranged relative to each other on both sides of the wire. At least a part of the common film is broken in the area that overlaps the wire and is spaced apart from the wire to form a first opening. In the embodiment of the disclosure, within the same pixel unit, the part of the common film layer located in the first sub-pixel and the part of the common film layer located in the second sub-pixel are broken at the first opening, so that the crosstalk generated by the transverse flow of the current along the common film layer due to the distance between the first sub-pixel and the second sub-pixel being too close can be reduced, so as to avoid when only the first sub-pixel needs to be lit up for image display or only the second sub-pixel needs to be lit up for image display, the risk that the second sub-pixel and the first sub-pixel will be lit at the same time due to current crosstalk. For example, when applied to the anti-peeping mode, the anti-peeping effect can be improved.

### BRIEF DESCRIPTION OF FIGURES

In order to illustrate more clearly the technical solutions of the embodiments of the present disclosure, the drawings that need to be used in the embodiments of the present disclosure will be briefly described below, and it is obvious that the drawings introduced below are only some embodiments of the present disclosure, and for those skilled in the art, other drawings can also be obtained according to these drawings without creative labor.

FIG. 1 is the first top view of the structure of the display substrate provided by an embodiment of the present disclosure;

FIG. 2 is the first cross-sectional view of the structure of the display substrate provided by an embodiment of the present disclosure;

FIG. 3A is a schematic diagram of the manufacturing process of the common film provided by an embodiment of the present disclosure;

FIG. 3B is the first schematic diagram of the manufacturing process of the display substrate provided by an embodiment of the present disclosure;

FIG. 3C is the second schematic diagram of the manufacturing process of the display substrate provided by an embodiment of the present disclosure;

FIG. 3D is the third schematic diagram of the manufacturing process of the display substrate provided by an embodiment of the present disclosure;

FIG. 4 is a cross-sectional view of the structure of the organic light-emitting diode provided by an embodiment of the present disclosure;

FIG. 5 is the second cross-sectional view of the structure of the display substrate provided by an embodiment of the present disclosure;

FIG. 6A is the third cross-sectional view of the structure of the display substrate provided by an embodiment of the present disclosure;

FIG. 6B is the fourth cross-sectional view of the structure of the display substrate provided by an embodiment of the present disclosure;

FIG. 7 is the second top view of the structure of the display substrate provided by an embodiment of the present disclosure;

FIG. 8A is the third top view of the structure of the display substrate provided by an embodiment of the present disclosure;

FIG. 8B is the fourth top view of the structure of the display substrate provided by an embodiment of the present disclosure;

FIG. 8C is the fifth top view of the structure of the display substrate provided by an embodiment of the present disclosure;

FIG. 9A is the sixth top view of the structure of the display substrate provided by an embodiment of the present disclosure;

FIG. 9B is the seventh top view of the structure of the display substrate provided by an embodiment of the present disclosure;

FIG. 9C is the eighth top view of the structure of the display substrate provided by an embodiment of the present disclosure;

FIG. 10A is the ninth top view of the structure of the display substrate provided by an embodiment of the present disclosure;

FIG. 10B is the tenth top view of the structure of the display substrate provided by an embodiment of the present disclosure;

FIG. 10C is the fifth cross-sectional view of the structure of the display substrate provided by an embodiment of the present disclosure;

FIG. 11 is the sixth cross-sectional view of the structure of the display substrate provided by an embodiment of the present disclosure;

FIG. 12 is the equivalent circuit diagram of the pixel circuit provided by an embodiment of the present disclosure;

FIG. 13 is the first flow chart of the manufacturing method of the display substrate provided by an embodiment of the present disclosure;

FIG. 14 is the second flow chart of the manufacturing method of the display substrate provided by an embodiment of the present disclosure.

### DETAILED DESCRIPTION

In order to make the above-mentioned purpose, features and advantages of the present disclosure more obvious and easy to understand, the present disclosure will be further explained below in conjunction with the accompanying drawings and embodiments. However, example embodiments can be implemented in a variety of forms and should not be construed as confined to those described herein. On the contrary, the provision of these embodiments makes the present disclosure more comprehensive and complete, and comprehensively communicates the idea of an example embodiment to those skilled in the art. The same drawing marks in the diagram indicate the same or similar structures, and repeated descriptions of them will be omitted. The words used in this disclosure to express the position and direction are illustrated with the accompanying drawings as an example, but they may be changed as needed, and all changes made are covered by the scope of protection of this disclosure. The drawings disclosed in this document are for illustrative purposes only and do not represent true proportions.

With the gradual increase in the importance of personal privacy, more and more users have a strong demand for the anti-peeping function of electronic products such as mobile phones. At present, the anti-peeping film attached to the display screen of electronic products can play the role of anti-peeping, but cannot switch between the anti-peeping function and the sharing function. For example, when the user needs to share screen information with others, it is difficult to share a wide range because the viewing angle of the external anti-peeping film is narrow.

In some technical routes, the anti-peeping function is realized by dividing the pixel unit into anti-peeping sub-pixels and display sub-pixels, and only lighting the anti-peeping sub-pixels for image display in the anti-peeping mode; in a normal mode, the anti-peeping sub-pixels and the display sub-pixels are lit at the same time for image display, so as to realize the sharing function. For example, when above technical means is applied to the display substrate of organic light emitting diode (OLED), because part of the film layer that forms the anti-peeping sub-pixels and the part of the film that forms the display sub-pixels are made on the whole side during the production and communicate with each other to form a common film, the current crosstalk between the anti-peeping sub-pixels and the display sub-pixels is easy to occur through the common film and affect the anti-peeping effect.

In view of this, the embodiment of the present disclosure provides a display substrate for solving the current crosstalk problem between the anti-peeping sub-pixels and the display sub-pixels caused by a common film.

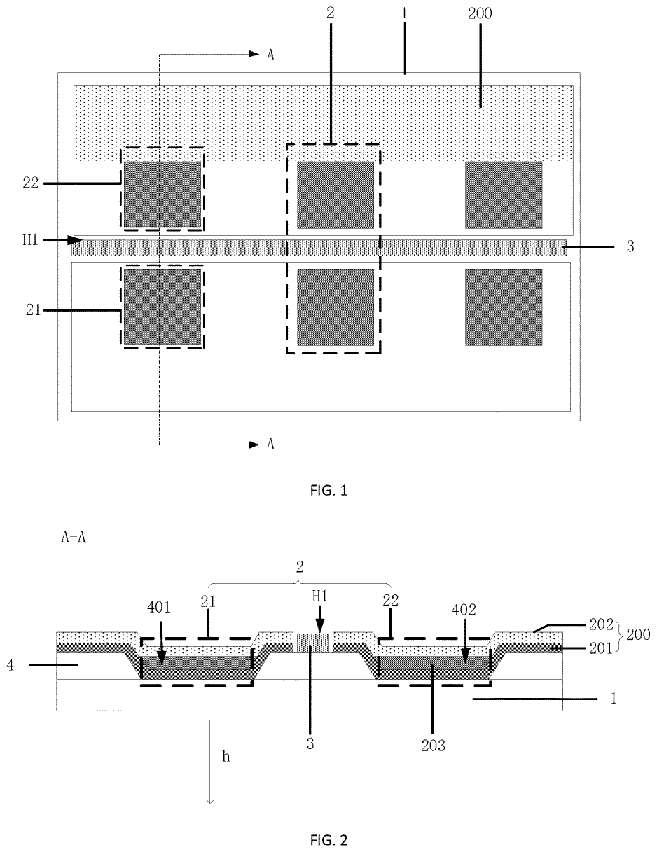

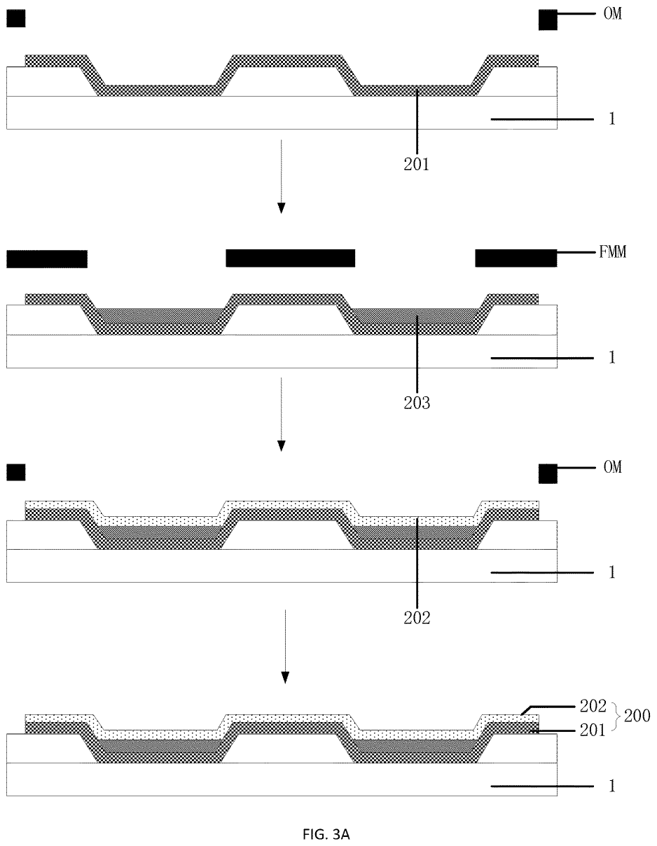

FIG. 1 is the first top view of the structure of the display substrate provided by an embodiment of the present disclosure. FIG. 2 is the first cross-sectional view of the structure of the display substrate provided by an embodiment of the present disclosure.

In the embodiment of the present disclosure, as shown in FIG. 1 and FIG. 2, the display substrate includes a substrate 1, a plurality of pixel units 2 and a wire 3. FIG. 2 is a cross-sectional view of FIG. 1 along the cross-sectional line A-A.

The substrate 1 is positioned at the bottom of the display substrate and is configured to bear the pixel units 2, the wire 3 and etc, which are arranged on the substrate 1. The shape and size of the substrate 1 are adapted to the shape and size of the display substrate. Specifically, the shape of the substrate 1 can be a conventional shape such as a square or rectangle, or a special shape such as a circle, and there is no restriction here. In some embodiments, the substrate 1 may be a rigid substrate made of a rigid material, such as glass, etc., to make a rigid display substrate. In some embodiments, the substrate 1 may be a flexible substrate made of flexible materials, such as polyimide, PI, etc., to make a flexible display substrate, and no limitation is made herein. In the specific implementation, the substrate 1 can be a single-layer structure or a multi-layer structure, and it is not limited here.

The plurality of pixel units 2 are located on the substrate 1. Each pixel unit 2 includes a first sub-pixel 21 and a second sub-pixel 22. The display substrate can have multiple display modes. In the first display mode, for one pixel unit 2, only the first sub-pixel 21 can be lit up for image display. In the second display mode, for one pixel unit 2, the first sub-pixel 21 and the second sub-pixel 22 can be lit up simultaneously for image display. In some display modes, for one pixel unit 2, it is also possible to light up only the second sub-pixel 22 for image display, and there is no limitation here. The first display mode can be an anti-peeping mode, the first sub-pixel 21 can be an anti-peeping sub-pixel. The first sub-pixel 21 is separately lit in the anti-peeping mode for image display, and the angle and brightness of the outgoing rays of the pixel unit 2 are small, so that the viewing angle in the anti-peeping mode is conducive to be reduced, and the anti-peeping effect is achieved. The second display mode can be a sharing mode, in which the first sub-pixel 21 and the second sub-pixel 22 are lit at the same time, and the angle and brightness of the outgoing rays of the pixel unit 2 are larger, so that more viewers are conducive to watching the display picture together. In some embodiments, in the sharing mode, for one pixel unit 2, only the second sub-pixel 22 may be lit up for image display. The specific embodiment can be carried out by increasing the luminous area of the second sub-pixel 22, increasing the driving current, etc., so as to improve the angle and brightness of the outgoing rays of the second sub-pixel 22, and enhance the sharing effect, and no limitation is made herein.

In the embodiment of the present disclosure, the first sub-pixel 21 and the second sub-pixel 22 can be fabricated through coating processes such as evaporation and deposition. For example, a part of films in the first sub-pixel 21 and the second sub-pixel 22 can be coated with an Open Mask (OM). An opening in OM can simultaneously expose all the pixel units 2 in the display region of the display substrate, which can effectively reduce the difficulty and cost of making the mask compared with the Fine Metal Mask (FMM). The OM is used for coating to form a film layer which covers the entire display region exposed by the opening of the OM. As shown in FIG. 1 and FIG. 2, the first sub-pixel 21 and the second sub-pixel 22 include a common film layer 200. In the manufacturing process, the common film layer 200 is made by coating the whole surface. For example, the common film layer 200 can be fabricated using the OM process.

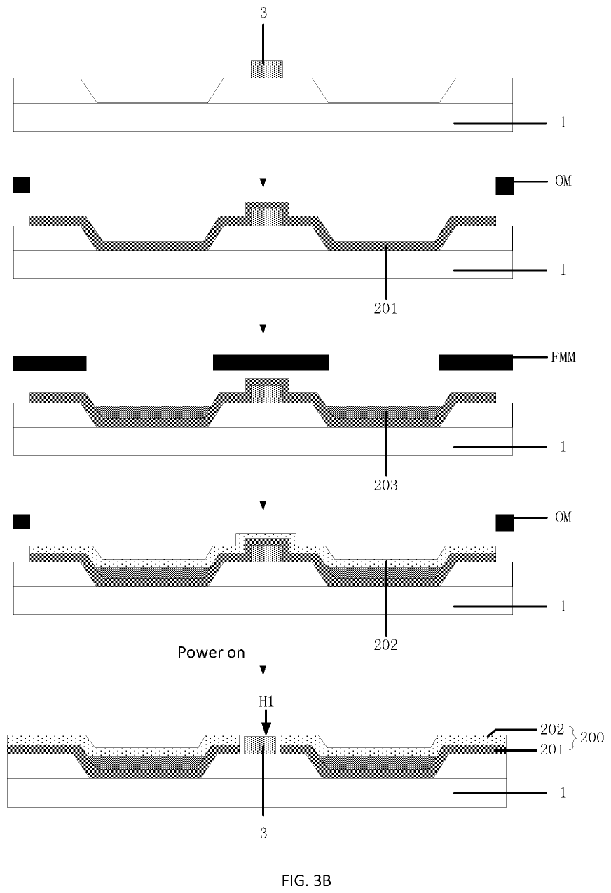

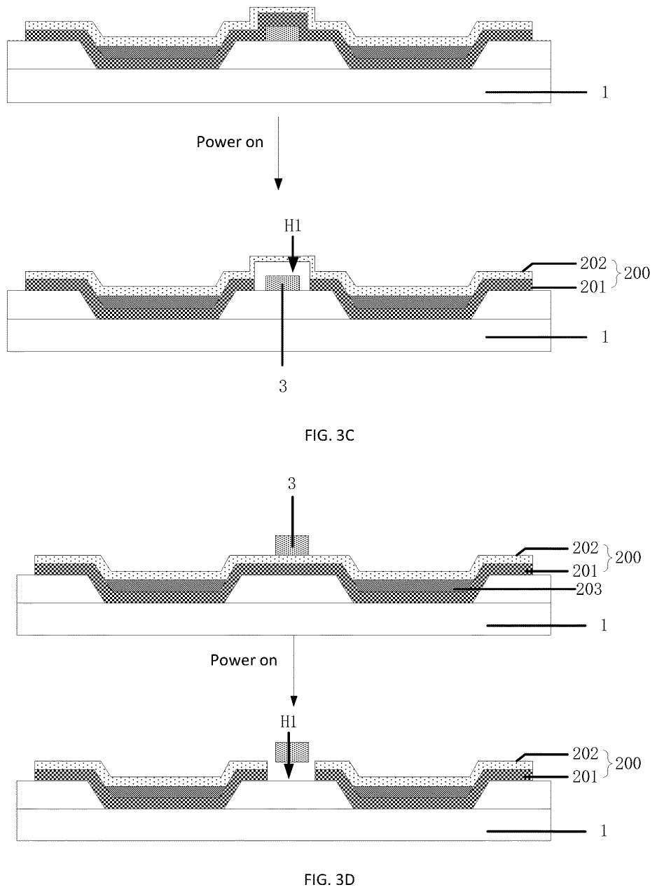

FIG. 3A is a schematic diagram of the manufacturing process of the common film layer provided by an embodiment the present disclosure.

As shown in FIG. 3A, taking the common film layer 200 of the first sub-pixel 21 and the second sub-pixel 22 including the first common film layer 201 and the second common film layer 202 as an example, the process of forming a common film layer 200 in the OM process is illustrated as an example. The first sub-pixel 21 and the second sub-pixel 22 further include a light-emitting layer 203 located between the first common film layer 201 and the second common film layer 202 respectively. One of the first common film layer 201 and the second common film layer 202 is electrically connected with the positive electrode of the power supply for transmitting holes, and the other one is electrically connected with the negative electrode of the power supply for transmitting electrons. The holes input by the positive electrode of the power supply and the electrons input by the negative electrode of the power supply are recombined in the light-emitting layer 203 to excite the outgoing light. Specifically, as shown in FIG. 3A, the formation process of the common film layer 200 includes at least the following steps.

1. Through the OM process, a first common film layer 201 is formed on one side of the substrate 1. The first common film layer 201 covers the entire surface of the area exposed by the opening of the OM, so that the part of the first common film layer 201 located at the corresponding position of the first sub-pixel 21 is interconnected with the part of the first common film layer 201 located at the corresponding position of the second sub-pixel 22.

2. Through the FMM process, the light-emitting layer 203 is formed on a side away from the substrate 1, of the first common film layer 201. The FMM is provided with an opening corresponding to the first sub-pixel 21 and the second sub-pixel 22. The material of the light-emitting layer is formed at the positions corresponding to the first sub-pixel 21 and the second sub-pixel 22 through the openings of the FMM, forming a part of the light-emitting layer 203 belonging to the first sub-pixel 21 and a part of the light-emitting layer 203 belonging to the second sub-pixel 22, respectively. The light-emitting layer 203 of the first sub-pixel 21 and the light-emitting layer 203 of the second sub-pixel 22 in the same pixel unit 2 are mutually insulated and spaced at intervals.

3. Through the OM process, the second common film layer 202 is formed on a side away from the substrate 1, of the light-emitting layer 203. The second common film layer 202 covers the entire surface of the area exposed by the opening of the OM, so that a part of the second common film layer 202 located at the position corresponding to the first sub-pixel 21 is interconnected with a part of the second common film layer 202 located at the corresponding position of the second sub-pixel 22.

In specific embodiment, the first common film layer 201 and the second common film layer 202 may both include at least one layer. In the manufacturing process shown in FIG. 3A, all layers included in the first common film layer 201 and all layers included in the second common film layer 202 are arranged on the entire surface of the display region of the display substrate to form a common film layer 200.

In some embodiments, the common film layer of the first sub-pixel 21 and the second sub-pixel 22 may also include only a part of all the layers of the common film layer 200 formed during the manufacturing process shown in FIG. 3A. For example, in the manufacturing process, only a part of the first common film layer 201 shown in FIG. 3A can be fabricated by the OM process, so that the part of the first common film layer covers the entire surface area exposed by the opening of OM. The remaining part of the first common film layer 201 shown in FIG. 3A is fabricated by the FMM process, so that the remaining part of the first common film layer is only formed in the area corresponding to the first sub-pixel 21 and the area corresponding to the second sub-pixel 22. The layers formed in the areas corresponding to the first sub-pixel 21 and the second sub-pixel 22 are separated from each other. Similarly, only a part of the second common film layer 202 shown in FIG. 3a can be fabricated by the OM process, so that the part of the second common film layer covers the entire area exposed by the opening of OM. The rest of the second common film layer 202 shown in FIG. 3A is fabricated by the FMM process, so that the remaining part of the second common film layer is formed only in the areas corresponding to the first sub-pixel 21 and the second sub-pixel 22. The film layers formed in the area corresponding to the first sub-pixel 21 and the area corresponding to the second sub-pixel 22 are separated from each other, respectively.

In some embodiments, the first sub-pixel 21 and the second sub-pixel 22 in the same pixel unit 2 may be used to emit rays of the same color. For example, the light-emitting layer of the first sub-pixel 21 and the light-emitting layer of the second sub-pixel 22 in the same pixel unit 2 can be made of the same material. Because the distance between the first sub-pixel 21 and the second sub-pixel 22 in the same pixel unit 2 is close, for the light-emitting layer of the first sub-pixel 21 and the light-emitting layer of the second sub-pixel 22 adopting the same material, when the light-emitting layer is made by evaporation and other processes, only the openings corresponding to the first sub-pixel 21 and the second sub-pixel 22 need to be set up at adjacent positions on the FMM, and then the light-emitting layer of the first sub-pixel 21 and the light-emitting layer of the second sub-pixel 22 can be made simultaneously in one evaporation process. Compared with the light-emitting layer of the first sub-pixel 21 and the light-emitting layer of the second sub-pixel 22 in the same pixel unit 2 are made of different materials, it can reduce the risk of crosstalk between materials of the light-emitting layer of the first sub-pixel 21 and the light-emitting layer of the second sub-pixel 22 in the same pixel unit 2 due to the inaccurate alignment of FMM. The first sub-pixel 21 and the second sub-pixel 22 in the same pixel unit 2 emit rays of the same color, so that the development difficulty of the control chip and the control algorithm for controlling the luminescence of the pixel unit 2 can also be reduced.

The wire 3 may be located on one side of the common film layer 200 and be arranged adjacent to the common film layer 200. For at least a part of the pixel units 2, the orthographic projection of the first sub-pixel 21 on the substrate 1 and the orthographic projection of the second sub-pixel 22 on the substrate 1 are arranged on both sides of the wire 3 relatively. At least a part of the common film layer 200 is broken in the area overlapping with the wire 3 and are arranged at a certain distance from the wire 3 to form the first opening H1 for accommodating the wire 3. The wire 3 is made of conductive materials, and specifically metal conductive layer materials such as aluminum (Al), silver (Ag), and molybdenum (Mo), and there is no restriction here.

In the embodiment of the disclosure, in at least a part of the common film layer 200 is broken at the first opening H1 within at least a part of the pixel units 2. The number of layers connected between the first sub-pixel 21 and the second sub-pixel 22 in at least part of the pixel units 2 can be reduced, thereby reducing the crosstalk generated by the current flowing transversely along the common film layer 200 in the part of the pixel units 2 due to the distance between the first sub-pixel 21 and the second sub-pixel 22 being too short, thereby reducing the risk that the second sub-pixel 22 and the first sub-pixel 21 are lit at the same time due to current crosstalk when only the first sub-pixel 21 is required to be lit for image display or only the second sub-pixel 22 is required to be lit for image display. For example, when applied to the anti-peeping mode, the anti-peeping effect can be improved.

In some embodiments, the orthographic projection of the first sub-pixel 21 on the substrate 1 and the orthographic projection of the second sub-pixel 22 on the substrate 1 may be arranged relative to both sides of the wire 3 in a part of pixel units 2, so that the common film layer of the first sub-pixel 21 and the second sub-pixel 22 only in the part of pixel units 2 forms a first opening H1. In the specific embodiment, the number and position of the pixel unit 2 in which the wire 3 need to be arranged between the first sub-pixel 21 and the second sub-pixel 22, can be flexibly selected according to the demand, and no limitation is made herein. For example, if the anti-peeping function only needs to be realized in a specific display region of the display substrate, then only the first sub-pixel 21 and the second sub-pixel 22 in the pixel unit 2 in the specific area can be arranged on both sides of the wire 3.

In some embodiments, the orthotropic projection of the first sub-pixel 21 on the substrate 1 and the orthographic projection of the second sub-pixel 22 on the substrate 1 can be arranged on both sides of the wire 3 in each pixel unit 2 on the display substrate. For example, in the anti-peeping mode, the anti-peeping effect can be improved throughout the entire display region of the display substrate. No limitation is made here.

Specifically, the wire 3 can be made before forming a common film layer 200. After making the wire 3, a common film layer 200 is directly formed on the surface of the wire 3. The wire 3 can also be directly made on the surface of the common film layer 200 after the formation of the common film layer 200, and it is not limited here. For example: after the wire 3 and the common film layer 200 are made, a voltage is applied to the wire 3 to form the current flowing along the wire 3. The wire 3 generates high temperature due to the heating of the power-on, to ablate the common film layer 200 which is in contact with the wire 3. At least a part of the common film layer 200 is broken in the ablated area, forming the first opening H1 for accommodating the wire 3. In the specific manufacturing process, the wire 3 is directly in contact with the common film layer 200, which is conducive to ablate the common film layer 200 by the wire 3. In the specific implementation, an interval layer can also be arranged between the wire 3 and the common film layer 200, and it is not limited herein.

FIG. 3B is one of the schematic diagrams of the manufacturing process of the display substrate provided by an embodiment of the present disclosure.

As shown in FIG. 3B, taking the first sub-pixel 21 and the second sub-pixel 22 both including a first common film layer 201, a second common film layer 202 and a light-emitting layer 203 located between the first common film layer 201 and the second common film layer 202, and forming a common film layer 200 after making the wire 3 as an example, the manufacturing process of the display substrate provided in the present disclosure embodiment is illustrated. As shown in FIG. 3B, the manufacturing process of the display substrate can include the following steps.
1. Through sputtering deposition and other processes, a conductive layer is formed by depositing conductive materials on one side of the substrate 1, and the conductive layer is etched to form a pattern of the wire 3 through patterning processes such as exposure, development, etching, or directly form the pattern of the wire 3 through the metal mask process.
2. Through the OM process, a first common film layer 201 is formed on a side away from the substrate 1, of the wire 3.
3. Through the FMM process, a light-emitting layer 203 is formed on a side from the substrate 1, of the first common film layer 201; the light-emitting layer 203 of at least part of the first sub-pixel 21 and the light-emitting layer 203 of at least part of the second sub-pixel 22 are spaced on both sides of the wire 3.
4. Through the OM process, a second common film layer 202 is formed on a side away from the substrate 1, of the light-emitting layer 203.
5. A voltage is applied to the wire 3 to form a current circulating on the wire 3. The wire 3 generates high temperature when it is heated, to ablate the first common film layer 201 and the second common film layer 202 sequentially, so that the first common film layer 201 and the second common film layer 202 are broken in an area corresponding to the wire 3, and an opening exposing the wire 3 is formed. In the area where no wire 3 is arranged, the first common film layer 201 remains connected, and the second common film layer 202 remains connected.

In the manufacturing process shown in FIG. 3A, when a voltage is applied to the wire 3 to form an electric current, so that the wire 3 heats up and ablates the common film layer 200, the wire 3 of high-temperature can ablate all the layers in the common film layer 200 along the direction far away from the substrate 1, so that the first opening H1 that penetrates through the common film layer 200 is formed. As shown in FIG. 3B, the first opening H1 exposes the wire 3, and the wire 3 is accommodated in the first opening H1, so that the current crosstalk between the first sub-pixel 21 and the second sub-pixel 22 in the same pixel unit 2 can be minimized.

FIG. 3C is the second schematic diagram of the manufacturing process of the display substrate provided by an embodiment of the present disclosure.

In some embodiments, as shown in FIG. 3C, when a voltage is applied to the wire 3 to form a current, so that the wire 3 is heated up to ablate the common film layer 200, the wire 3 of high-temperature can ablate only a part of the common film layer 200 in the direction away from the substrate 1, so that only part of layers in all the film layers of the common film layer 200 are ablated and broken, and the rest of all the film layers remain connected. For example, in an organic light-emitting diode display panel, the cathode of the organic light-emitting diode is usually arranged on a side away from the substrate 1, and the cathode of the organic light-emitting diode is usually made on the whole surface by OM process and used as a common electrode, so that when the common film layer is ablated by the wire 3 of high-temperature, the cathode layer of the organic light-emitting diode in the common film layer cannot be ablated, so as to retain the common electrode effect of the cathode of the organic light-emitting diode. In specific implementation, a part of conductive film layers arranged adjacent to the cathode of the organic light-emitting diode can also be retained to act as an auxiliary electrode to reduce the resistance of the common electrode. As shown in FIG. 3C, the common film layer 200 forms a first opening H1 that does not penetrate through the common film layer 200 in the area corresponding to the wire 3, and the wire 3 is accommodated in the first opening H1.

FIG. 3D is the third schematic diagram of the manufacturing process of the display substrate provided by an embodiment of the present disclosure.

In some embodiments, as shown in FIG. 3D, the common film layer 200 can be made on one side of substrate 1 before wire 3 is fabricated. For example, the first common film layer 201 is made through the OM process, the light-emitting layer 203 is made through the FMM process, and the second common film layer 202 is made through the OM process to form a common layer 200 in turn. The wire 3 is then formed on a side away from the substrate 1, of the common film layer 200. The wire 3 is located between the light-emitting layer 203 of at least part of the first sub-pixel and the light-emitting layer 203 of at least part of the second sub-pixel. After the wire 3 is made, the wire 3 is heated by electricity to ablate the common film layer 200 to form the first opening H1. In some embodiments, all layers in the common film layer can be ablated to form a first opening H1 penetrating through the common film layer. In some embodiments, a part of the common film layer can be ablated to form a first opening H1 which does not penetrate the common film layer. No limitation is made here. In some embodiments, as shown in FIG. 3D, after the wire 3 ablates a common film layer located below the wire 3, the wire 3 is suspended due to loss of support. In some embodiments, after the wire 3 ablates the common film layer located below the wire 3, the wire 3 sags to be in contact with the film layer exposed by the first opening H1 after ablating the common film layer, and then is supported through the film layer exposed by the first opening H1. No limitation is made here.

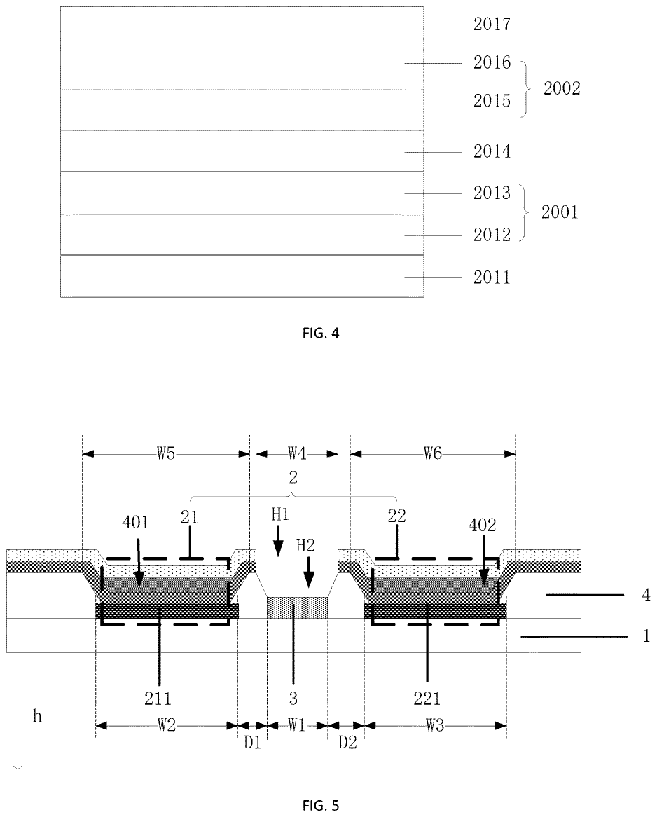

FIG. 4 is a cross-sectional view of the structure of the organic light-emitting diode provided by an embodiment of the present disclosure.

In some embodiments, the first sub-pixel 21 and the second sub-pixel 22 may both be organic light-emitting diodes.

As shown in FIG. 4, the organic light-emitting diode includes a first electrode layer 2011, a first functional layer 2001, an organic light-emitting layer 2014, a second functional layer 2002, and a second electrode layer 2017, which are arranged in a stack manner. In specific implementation, the first electrode layer 2011 can be arranged on a side close to the substrate 1, and the second electrode layer 2017 can be arranged on a side away from the substrate 1. The first functional layer 2001 includes at least one film layer. The second functional layer 2002 includes at least one film layer. At least one of all layers of the first functional layer 2001, the second functional layer 2002 and the second electrode layer 2017 can be manufactured by the OM process, so that the common film layer 200 includes at least one layer in all the layers of the first functional layer 2001, the second functional layer 2002 and the second electrode layer 2017.

In some embodiments, the first electrode layer 2011 serving as an anode of an organic light-emitting diode is connected with the positive electrode of a power supply for input holes. The second electrode layer 2017 serving as a cathode of the organic light-emitting diode is connected to the negative electrode of the power supply for the input electrons. The holes and the electrons are input into the organic light-emitting layer 2014 through the first functional layer 2001 and the second functional layer 2002, respectively, and the holes and the electrons are recombined in the organic light-emitting layer 2014 to excite the outgoing light. In some embodiments, the first functional layer 2001 may include a hole transport layer 2013 and a hole injection layer 2012 that are stacked in a direction away from the organic light-emitting layer 2014. The second functional layer 2002 includes an electron transport layer 2015 and an electron injection layer 2016 that are stacked in a direction away from the organic light-emitting layer. In specific implementation, the first functional layer 2001 and the second functional layer 2002 may also include more or less film layers, and are not limited herein.

In some embodiments, the first electrode layer 2011 served as the cathode of the organic light-emitting diode is connected with the negative electrode of a power supply for input electrons. The second electrode layer 2017 served as the anode of the organic light-emitting diode is connected with the positive electrode of the power supply for input holes. The electrons and the holes are input into the organic light-emitting layer 2014 through the first functional layer 2001 and the second functional layer 2002, respectively, and the holes and the electrons are recombined in the organic light-emitting layer 2014 to excite the outgoing light. In some embodiments, the first functional layer 2001 may include an electron transport layer 2013 and an electron injection layer 2012that are stacked in a direction away from the organic light-emitting layer 2014. The second functional layer 2002 includes a hole transport layer 2015 and a hole injection layer 2016 that are stacked in a direction away from the organic light-emitting layer. In specific implementation, the first functional layer 2001 and the second functional layer 2002 may also include more or less film layers, and are not limited herein.

Normally, the first electrode layer 2011 served as the anode of the organic light-emitting diode can be arranged on a side close to substrate 1, and the second electrode layer 2017 served as the cathode of the organic light-emitting diode can be arranged on a side away from substrate 1. No limitation is made here.

In the specific embodiment, the first sub-pixel 21 and the second sub-pixel 22 may also be other light-emitting elements other than organic light-emitting diodes, and are not limited herein.

In some embodiments, as shown in FIG. 2, the display substrate also includes a pixel definition layer 4. The pixel definition layer 4 is located on a side of substrate 1. The pixel definition layer 4 is provided with a first pixel opening 401 and a second pixel opening 402 that penetrate through the pixel definition layer 4 in a thickness direction h of the pixel definition layer 4. The common film layer 200 is located on a side away from substrate 1, of the pixel definition layer 4, and is partly located between the first pixel opening 401 and the second pixel opening 402. The orthographic projection of the common film layer 200 located between the first pixel opening 401 and the second pixel opening 402 on the substrate 1 overlaps with the orthographic projection of the pixel definition layer 4 on the substrate 1.

The first sub-pixel 21 is at least partially located in the first pixel opening 401. The second sub-pixel 22 is at least partially located in the second pixel opening 402. The first sub-pixel 21 being at least partially located in the first pixel opening 401 and the second sub-pixel 22 being at least partially located in the second pixel opening 402, specifically means each of layers forming the first sub-pixel 21 is at least partially located in the first pixel opening 401, and each of layers forming the second sub-pixel 22 is at least partially located in the second pixel opening 402. For example, the common film layer 200 for forming the first sub-pixel 21 and the second sub-pixel 22 is partly located in the first pixel opening 401 and the second pixel opening 402, and partly on the surface of the pixel definition layer 4 outside the first pixel opening 401 and the second pixel opening 402. For example, the light-emitting layers 203 used to form the first sub-pixel 21 and the second sub-pixel 22 respectively may all be located in the first pixel opening 401 and the second pixel opening 402. In the specific embodiment, the first sub-pixel 21 and the second sub-pixel 22 are separated by a part of pixel definition layer 4 located between the first pixel opening 401 and the second pixel opening 402.

In the specific embodiment, for each pixel unit 2, the orthotropic projection of the first pixel opening 401 on the substrate 1 and the orthographic projection of the second pixel opening 402 on the substrate 1 are positioned at both sides of the orthographic projection of the wire 3 on the substrate 1.

In some embodiments, as shown in FIG. 2, the wire 3 is located on a side away from substrate 1, of the pixel definition layer 4. Specifically, the wire 3 can be made after the pixel definition layer 4 is made, and the wire 3 can be made on the surface of the pixel definition layer 4, so as to avoid trepanning an opening in the pixel definition layer 4 to expose the wire 3.

In some embodiments, as shown in FIG. 2, the wire 3 is located between the common film layer 200 and the pixel definition layer 4. The wire 3 being located between the common film layer 200 and the pixel definition layer 4, specifically means that before making the common film layer 200, the wire 3 is formed on a side away from the substrate 1, of the pixel definition layer 4, and then the common film layer 200 is formed on a side away from the pixel definition layer 4, of the wire 3. Thus, after the common film layer 200 is ablated by the wire 3, the wire 3 can also be supported by the pixel definition layer 4 below the wire 3, and the stability of the structure is improved.

In some embodiments, as shown in FIG. 3D, the wire 3 is located on a side away from the pixel definition layer 4, of the common film layer 200. The wire 3 being located on a side away from the pixel definition layer 4, of the common film layer 200, specifically means that before making the wire 3, the common film layer 200 is formed on a side away from the substrate 1, of the pixel definition layer 4, and then the wire 3 is formed on the side away from the pixel definition layer 4, of the common film layer 200. Adopting this arrangement mode, there is no need to change the process steps of making the pixel definition layer 4 and the common film layer 200 in the related technology, and the coating process of the common film layer 200 is relatively mature in the related technology.

FIG. 5 is the second cross-sectional view of the structure of the display substrate provided by an embodiment of the present disclosure.

In some embodiments, as shown in FIG. 5, the wire 3 is located on the side away from the common film layer 200, of the pixel definition layer 4. The wire 3 being located on the side away from the common film layer 200, of the pixel definition layer 4, specifically means that before making the pixel definition layer 4, the wire 3 is first made, then a pixel definition layer 4 is formed on the side away from the substrate 1, of the wire 3, and the common film layer 200 is formed on the side away from the wire 3, of the pixel definition layer 4.

As shown in FIG. 5, the pixel definition layer 4 also has a second opening H2. The second opening H2 penetrates through the pixel definition layer 4 in the thickness direction h of the pixel definition layer 4 and exposes the wire 3. At least a part of the common film layer 200 is broken at the position of the second opening H2, to form the first opening H1. During specific production, the common film layer 200 is filled in the second opening H2 during manufacturing, and contacts with the wire 3. After the wire 3 is energized, the common film layer 200 in contact with the wire 3 is ablated, so that at least a part of in common film layer 200 is broken at the position of the second opening H2, and the first opening H1 is formed. In the specific embodiment, the area of the orthographic projection of the first opening H1 on the substrate 1 depends on the material and width of the wire 3, the magnitude of the current applied on the wire 3 and the heating time, and does not limit the relationship between the area of the orthographic projection of the first opening H1 on the substrate 1 and the area of the orthotropic projection of the second opening H2 on the substrate 1.

In the specific embodiment, as shown in FIG. 5, the display substrate further includes a first electrode 211 and a second electrode 221 located between the pixel definition layer 4 and the substrate 1. The first electrode 211 and the second electrode 221 are arranged at intervals. The orthographic projection of the first electrode 211 on the substrate 1 overlaps at least partially with the orthographic projection of the first pixel opening 401 on the substrate 1. The orthographic projection of the second electrode 221 on the substrate 1 overlaps at least partially with the orthographic projection of the second pixel opening 402 on the substrate 1. The first electrode 211 is configured to form the first sub-pixel 21 and the second electrode 221 is configured to form the second sub-pixel 22. When the first sub-pixel 21 and the second sub-pixel 22 are both organic light-emitting diodes, as shown in FIG. 4 and FIG. 5, the first electrode 211 and the second electrode 221 are arranged on the first electrode layer 2011 which is on a side close to the substrate 1, of the organic light-emitting diode. The first electrode 211 may be the anode or cathode of the first sub-pixel 21, and the second electrode 221 may be the anode or cathode of the second sub-pixel 22.

In the specific embodiment, as shown in FIG. 5, for each pixel unit 2, the orthographic projection of the first electrode 211 on the substrate 1 and the orthographic projection of the second electrode 221 on the substrate 1 are positioned at both sides of the orthographic projection of the wire 3 on the substrate 1.

In some embodiments, as shown in FIG. 5, the wire 3 is located in a conductive film layer same as a layer where the first electrode 211 and the second electrode 221 are. The wire 3, the first electrode 211 and the second electrode 221 are separated by a part of pixel definition layer 4 located between the wire 3 and the first electrode 211 and a part of pixel definition layer 4 located between the wire 3 and the second electrode 221. The wire 3 being located in the conductive film layer same as the layer where the first electrode 211 and the second electrode 221 are, specially means that the wire 3 and the first electrode 211 and the second electrode 221 can be made in the conductive film layer formed in the same process step through the same patterning process, thereby helping to reduce the number of film layers of the display substrate, reducing the difficulty of manufacturing the display substrate, and thinning the thickness of the display substrate.

In some embodiments, as shown in FIG. 5, between the first electrode 211 and the second electrode 221, the width W1 of the wire 3 is smaller than the width W2 of the first electrode 211 and the width W3 of the second electrode 221. Under the premise of ensuring that the common film layer can achieve the predetermined ablation effect, the width of the wire 3 can be reduced as much as possible, so that the wire 3 can be avoided from occupying the arrangement area of the first electrode 211 and the second electrode 221 too much, which is conducive to increasing the orthographic areas of the first sub-pixel 21 and the second sub-pixel 22 on the substrate 1, and then increasing the area of the display region. Specifically, the width W1 of the wire 3, the width W2 of the first electrode 211 and the width W3 of the second electrode 221 refer to the width in the direction perpendicular to the extension direction of the wire 3.

In some embodiments, the width W4 of the second opening H2 of the pixel definition layer 4 corresponding to the wire 3 is smaller than the width W5 of the first pixel opening 401 and the width W6 of the second pixel opening 402 located on both sides of the second opening H2, so that the space utilization rate of the display substrate is improved and the area occupied by the display region is increased. Specifically, the width W4 of the second opening H2, the width W5 of the first pixel opening 401, and the width W6 of the second pixel opening 402 refer to the width in the direction perpendicular to the extension direction of the second opening H2.

In some embodiments, as shown in FIG. 5, the spacing D1 between the wire 3 and the first electrode 211 is smaller than the spacing D2 between the wire 3 and the second electrode 221, so that the design is conducive to ensuring that the wire 3 obstructs the first sub-pixel 21. For example, the crosstalk to the second sub-pixel 22 when only the first sub-pixel 21 is lit for image display in the first display mode can be avoided as much as possible. Similarly, the width of the pixel defining layer 4 between the wire 3 and the first electrode 211 is smaller than the width of the pixel defining layer 4 between the wire 3 and the second electrode 221, and smaller than the width of the pixel defining layer 4 between the adjacent pixel units 2.

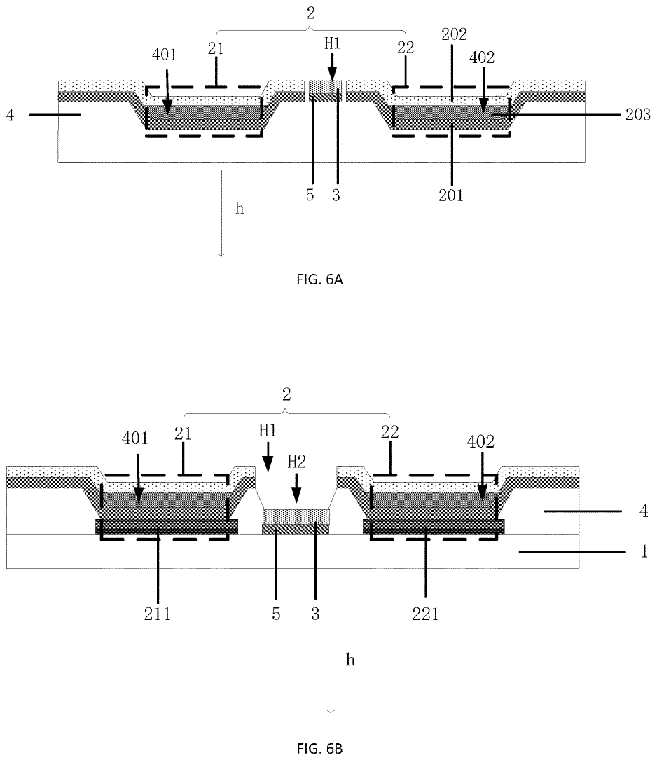

FIG. 6A is the third cross-sectional view of the structure of the display substrate provided by an embodiment of the present disclosure. FIG. 6B is the fourth cross-sectional view of the structure of the display substrate provided by an embodiment of the present disclosure.

In some embodiments, the display substrate further includes a thermal insulation layer. The thermal insulation layer is located on a side away from the common film layer 200, of the wire 3. The orthographic projection of the wire 3 on the substrate 1 is located within the orthographic projection of the thermal insulation layer on the substrate 1. For example, the thermal insulation layer is arranged in contact with the wire 3 to prevent the ablation of the film layer located on the side away from the common film layer 200, of the wire 3 after the wire 3 is heated by electricity.

In some embodiments, as shown in FIG. 6A and FIG. 6B, the thermal insulation layer 5 is arranged on a side facing the substrate 1, of the common film layer 200, and the wire 3 is located between the thermal insulation layer and the common film layer 200. Specifically, before manufacturing the wire 3, the thermal insulation layer 5 can be manufactured in advance, and then the wire 3 is manufactured on the side away from the substrate 1, of the thermal insulation layer 5, and the common film layer 200 is manufactured on the side away from the thermal insulation layer 5, of the wire 3. When the common film layer 200 is ablated by energizing the wire 3, the common film layer 200 can be ablated immediately after the production of the common film layer 200 is completed. The common film layer 200 can also be ablated by energizing the wire 3 after the production of the common film layer 200 and other film layers located on the side away from the substrate 1, of the common film layer 200, and no limitation is made here.

In some embodiments, the thermal insulation layer may be arranged on a side away, from the substrate 1, of the common film layer 200, and the wire 3 is located between the thermal insulation layer and the common film layer 200. Specifically, after manufacturing the common film layer 200, the wire 3 and the thermal insulation layer are manufactured sequentially, and after the thermal insulation layer is made, other film layers of the display substrate that are positioned on the side away from the substrate 1, of the thermal insulation layer can be continuously manufactured. After the film layers of the display substrate are made, the wire 3 is energized to ablate the common film layer 200. The heat insulation layer can prevent the wire 3 from ablating other film layers on the side away from the substrate 1, of the heat insulation layer.

In some embodiments, as shown in FIG. 6A and FIG. 6B, the orthographic projection of wire 3 on substrate 1 and the orthographic projection of thermal insulation layer 5 on substrate 1 completely coincide, so that the influence of thermal insulation layer on the thickness of the display substrate can be reduced, and the thickness of the display substrate is conducive to thinning.

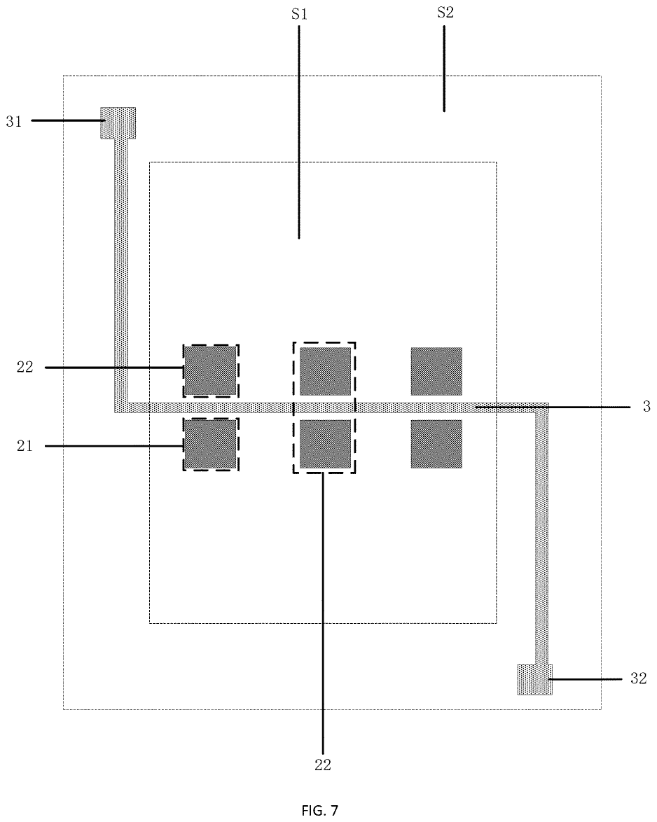

FIG. 7 is the second top view of the structure of the display substrate provided by an embodiment of the present disclosure.

In some embodiments, as shown in FIG. 7, the wire 3 include an input terminal 31 and an output terminal 32. The input terminal 31 and the output terminal 32 are respectively connected to a high-potential terminal and a low-potential terminal, and after being energized, an electric potential difference is formed between the input terminal 31 and the output terminal 32, and the current flowing from the output terminal 32 after flowing through the input terminal 31 and flowing through the wire 3 is formed. According to the current work done formula: P=UI, because the resistance of wire 3 changes less, the greater the potential difference U between the input terminal 31 and the output terminal 32 is, the greater the current I flowing through wire 3 is, then the power P of the current work done through wire 3 is also larger. The smaller the resistance of wire 3 is, the greater the power P of the current work done flowing through wire 3. Because the resistance of wire 3 is very small, it is equivalent to a short circuit between the input terminal 31 and the output terminal 32, so that the power of the current work done flowing through wire 3 is very large, and the wire 3 can quickly heat up and produce high temperature, so that the common film layer in contact with the wire 3 is ablated. In the specific embodiment, the input terminal 31 and the output terminal 32 are electrically connected to the positive electrode and negative electrode of the power supply respectively, thereby loading a voltage on the wire 3 to form a current. In some embodiments, the input terminal 31 and the output terminal 32 can be directly connected to the external power supply. When the ablation of the common film layer is carried out, the positive electrode and the negative electrode of the power supply are directly connected to the input terminal 31 and the output terminal 32 respectively, so as to load the voltage on the wire 3 to form a current. The power supply can be disconnected from the input terminal 31 and the output terminal 32 after the ablation is finished, and the power supply is withdrawn, so that the difficulty of routing the signal line can be reduced. In some embodiments, the input terminal 31 and the output terminal 32 may be connected to a signal circuit in the display substrate and then connected to a power supply through the signal circuit, and no limitation is made herein.

In the specific embodiment, as shown in FIG. 7, the display substrate includes a pixel region S1 and a non-pixel region S2. The pixel units 2 are arranged in the pixel region S1, and the non-pixel region S2 is used for setting up drive circuits such as Gate On Array (GOA) or elements such as driver chips. The input terminal 31 and the output terminal 32 of the wire 3 are also arranged in the non-pixel region S2, so that the input terminal 31 and the output terminal 32 of the wire 3 can be avoided from occupying the setting area of the pixel units 2, and the area of the display region is improved.

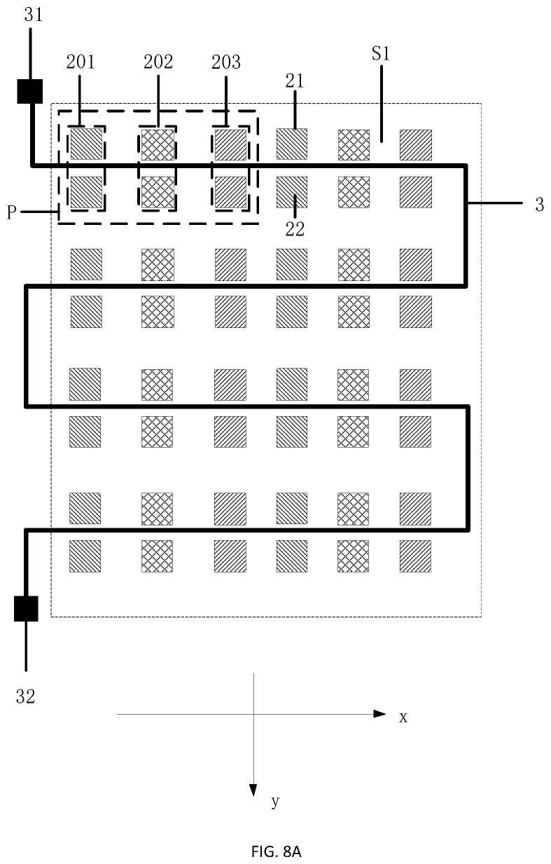

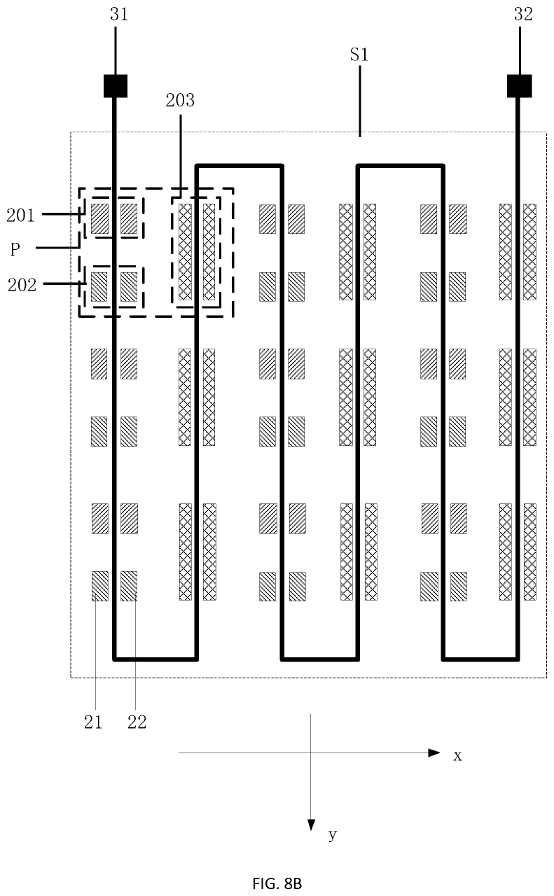

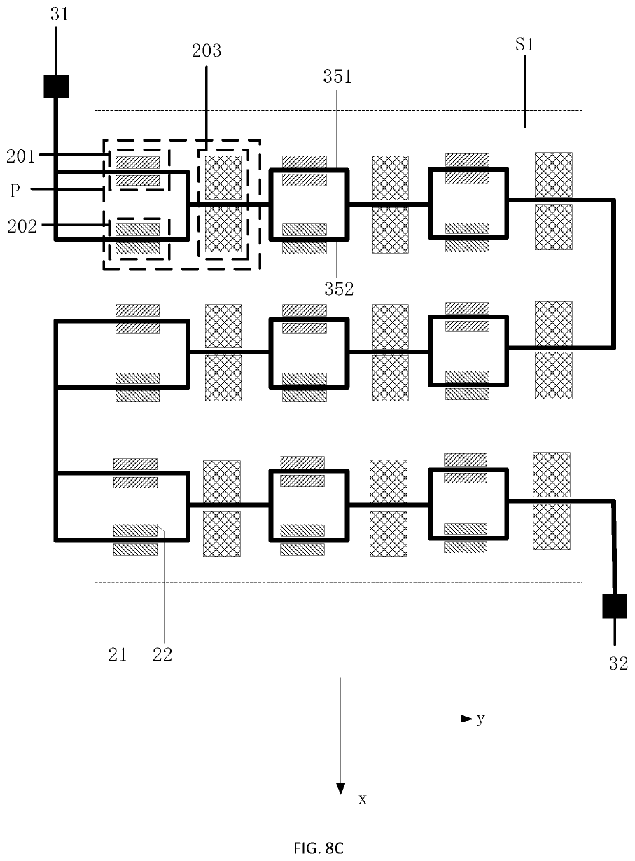

FIG. 8A is the third top view of the structure of the display substrate provided by an embodiment of the present disclosure. FIG. 8B is the fourth top view of the structure of the display substrate provided by an embodiment of the present disclosure. FIG. 8C is the fifth top view of the structure of the display substrate provided by an embodiment of the present disclosure.

In some embodiments, the wire 3 passes through each pixel unit 2 in the pixel region continuously, so that the first sub-pixel 21 and the second sub-pixel 22 in each pixel unit 2 are located on both sides of the wire 3. For example, the display substrate only needs to set one continuous wire 3 to ablate the common film layer 200 in all pixel units 2 in the pixel region S1, reducing the difficulty of setting the wire 3. Further, the current flowing through the wire 3 is the same, which is conducive to the formation of the first opening H1 of uniform size in the common film layer 200.

For example, as shown in FIG. 8A, a plurality of pixel units of the display substrate include a plurality of first pixel units 201, a plurality of second units 202 and a plurality of third pixel units 203. A first pixel unit 201, a second pixel unit 202 and a third pixel unit 203 arranged next to each other form a pixel group P. The first pixel units 201 can be used for emitting green rays, the second pixel units 202 can be used for emitting red rays, and the third pixel units 203 can be used for emitting blue rays, so that the display of color images is realized. When specifically setting, a plurality of first pixel units 201, a plurality of second units 202 and a plurality of third pixel units 203 can be set according to the arrangement of RGB. Specifically, as shown in FIG. 8A, the first pixel unit 201, the second pixel unit 202, and the third pixel unit 203 in the same pixel group P are arranged side by side along the first direction x, and a plurality of pixel groups P in the pixel region S1 are arranged in an array along the first direction x and the second direction y, respectively. The first direction x and the second direction y cross. As shown in FIG. 8A, the wire 3 can extend along the first direction x, pass through a plurality of pixel units located in the same row, so that the first sub-pixel 21 and the second sub-pixel 22 located in each pixel unit of the row are positioned on both sides of the wire 3. After the wire 3 turns along the second direction y on one side of the pixel region S1, it passes through the adjacent row of pixel units again, and the wire 3 continuously passes through each row of pixel units in the pixel region S1, so that the first sub-pixel 21 and the second sub-pixel 22 in each pixel unit in the pixel region S1 are positioned on both sides of the wire 3.

In the specific embodiment, the wire 3 can also pass through each column of pixel units in the pixel region S1 along the second direction y, so that the first sub-pixel 21 and the second sub-pixel 22 in each pixel unit in the pixel region S1 are both positioned on both sides of the wire 3. No limitation is made here.

As shown in FIG. 8B, the plurality of pixel units of the display substrate include a plurality of first pixel units 201, a plurality of second units 202 and a plurality of third pixel units 203. A first pixel unit 201, a second pixel unit 202 and a third pixel unit 203 arranged next to each other form a pixel group P. The first pixel units 201 can be used for emitting green rays, the second pixel units 202 can be used for emitting red rays, and the third pixel units 203 can be used for emitting blue rays, so that the display of color images is realized. Specifically, a plurality of first pixel units 201, a plurality of second units 202, and a plurality of third pixel units 203 can be set according to the arrangement of S-Stripe. Specifically, as shown in FIG. 8B, the first pixel unit 201 and the second pixel unit 202 in the same pixel group P are arranged side by side on the same side of the third pixel unit 203 along the second direction y. A plurality of pixel groups P in the pixel region S1 are arranged in an array along the first direction x and the second direction y, respectively. The first direction x and the second direction y cross. As shown in FIG. 8B, in a plurality of pixel groups P arranged in the same column along the second direction y, the first pixel units 201 and the second pixel units 202 arranged on the same side of the third pixel units 203 are arranged in a column along the second direction y, and the third pixel units 203 in the plurality of pixel groups P are arranged in a column along the second direction y. The wire 3 extends along the second direction y and passes through the first pixel units 201 and the second pixel units 202 located in the same column, so that the first sub-pixel 21 and the second sub-pixel 22 located in each pixel unit of the column are located on both sides of the wire 3. After the wire 3 turns along the first direction x on one side of the pixel region S1, it passes through the adjacent third pixel units 203 in the same column again, and the wire 3 continuously passes through each column of pixel units in the pixel region S1, so that the first sub-pixel 21 and the second sub-pixel 22 in each pixel unit in the pixel region S1 are located on both sides of the traverse 3.

As shown in FIG. 8C, a plurality of pixel units of the display substrate include a plurality of first pixel units 201, a plurality of second units 202 and a plurality of third pixel units 203. A first pixel unit 201, a second pixel unit 202 and a third pixel unit 203 arranged next to each other form a pixel group P. The first pixel units 201 can be used for emitting green rays, the second pixel units 202 can be used for emitting red rays, and the third pixel units 203 can be used for emitting blue rays, so that the display of color images is realized. Specifically, a plurality of first pixel units 201, a plurality of second units 202, and a plurality of third pixel units 203 can be set according to the arrangement of S-Stripe. In some embodiments, as shown in FIG. 8C, the first pixel unit 201 and the second pixel unit 202 in the same pixel group P are arranged side by side on the same side of the third pixel unit 203 along the first direction x, and a plurality of pixel groups P in the pixel region S1 are arranged in an array along the first direction x and the second direction y respectively. The first direction x and the second direction y cross. As shown in FIG. 8C, in a pixel group P, the first pixel unit 201 and the second pixel unit 202 are arranged side by side along the first direction x on the same side of the third pixel unit 203. The wire 3 includes a first branch 351 passing through the first pixel unit 201 and a second branch 352 passing through the second pixel unit 202 respectively, and the first branch 331 and the second branch 332 merge into a wire to pass through the third pixel unit 203 after passing through the first pixel unit 201 and the second pixel unit 202 respectively, so that in all pixel units in the pixel region S1, the first sub-pixels 21 and the second sub-pixels 22 are positioned at both sides of the wire 3. Adopting the mode of FIG. 8C, the wire 3 passes through the first pixel unit 201 and the second pixel unit 202 in parallel, so that the first pixel unit 201 and the second pixel unit 202 can be ablated synchronously, the ablation degree of the first pixel unit 201 and the second pixel unit 202 can be guaranteed to be basically the same, and the overall ablation time can be saved. Of course, adopting the mode of FIG. 8C, the annular structure formed by the wire 3 in the first pixel unit 201 and the second pixel unit 202 can also form a separation between the adjacent pixel units 2. for example, the wire 3 includes a first branch 351 passing through the first pixel unit 201 and a second branch 352 passing through the second pixel unit 202 respectively, and the first branch 351 can separate the first pixel unit 201 and the third pixel unit 203, the second branch 352 can separate the second pixel unit 202 and the third pixel unit 203.

In the embodiment shown in FIG. 8A~FIG. 8C, the wire 3 is not limited to passing through pixel units located in the same row along the first direction x or pixel units in the same column along the second direction y. The wire 3 may also pass through each pixel unit within the pixel region in other ways, for example, along a third direction (such as the direction of the diagonal of the array) between the first direction x and the second direction y, and is not limited herein.

In the embodiment shown in FIG. 8A~FIG. 8C, taking the pixel units arranged in accordance with the RGB mode and the S-Stripe mode as examples, the specific arrangement mode of each pixel unit 2 in which the wire 3 continuously passes through in the pixel region so that the first sub-pixel 21 and the second sub-pixel 22 in each pixel unit 2 are located on both sides of the wire 3, are illustrated as examples. In the specific implementation, the arrangement of the pixel units is not limited to the RGB mode or the S-Stripe method. For example, the pixel units can also be set according to the PenTile arrangement, the diamond arrangement, the Delta arrangement, the Triangular PenTile arrangement, and so on. The specific setting methods of the above various arrangements can refer to the relative art, and will not be repeated here. When the pixel units are arranged according to any of the above-mentioned arrangement modes, the wire 3 can be arranged to continuously pass through each pixel unit 2 in the pixel region, so that the first sub-pixel 21 and the second sub-pixel 22 in each pixel unit 2 are positioned at both sides of the wire 3, and the embodiments shown in FIG. 8A and FIG. 8B can be referred to when the specific setting is made, and is not repeated herein.

In the embodiment shown in FIG. 8A~FIG. 8C, a plurality of pixel units in the display substrate including a plurality of first pixel units 201, a plurality of second units 202 and a plurality of third pixel units 203 are used as an example to illustrate. In actual implementation, a plurality of pixel units in the display substrate may include more or less kinds of pixel units, for example, a plurality of pixel units in the display substrate can be pixel units that emit rays of the same color, so as to realize monochrome display, and no limitation is made herein.

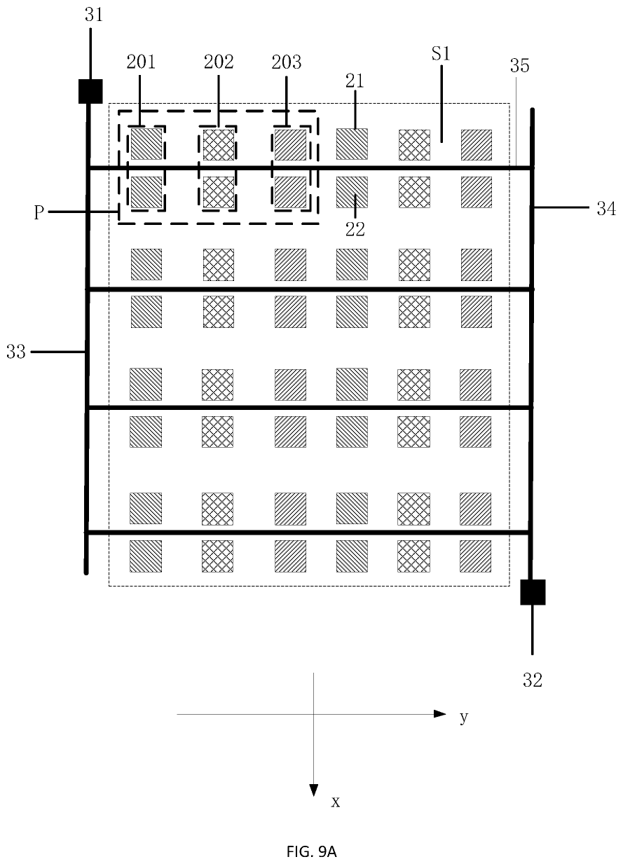

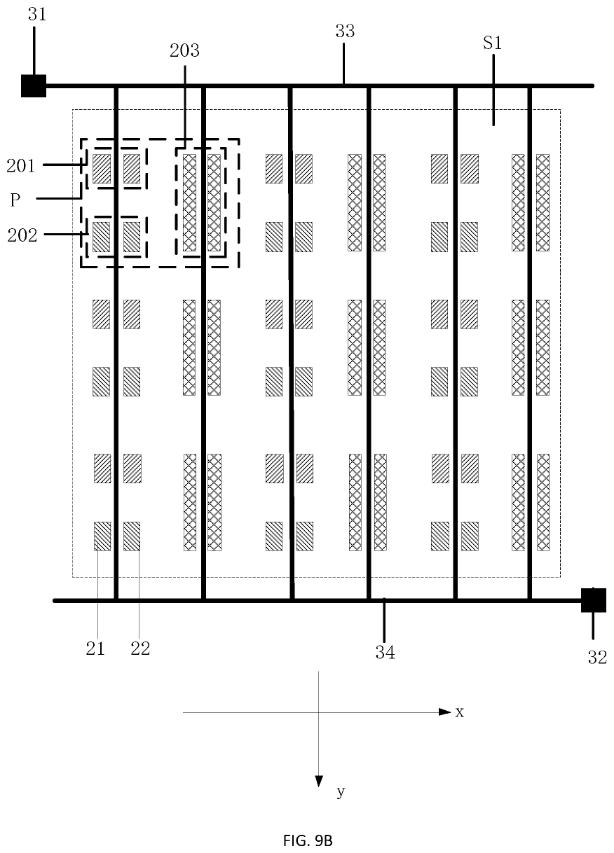

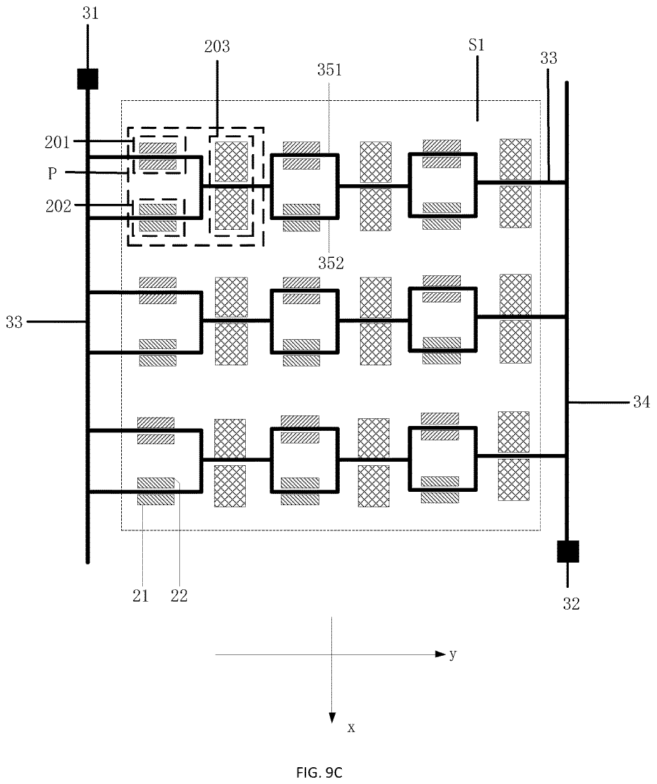

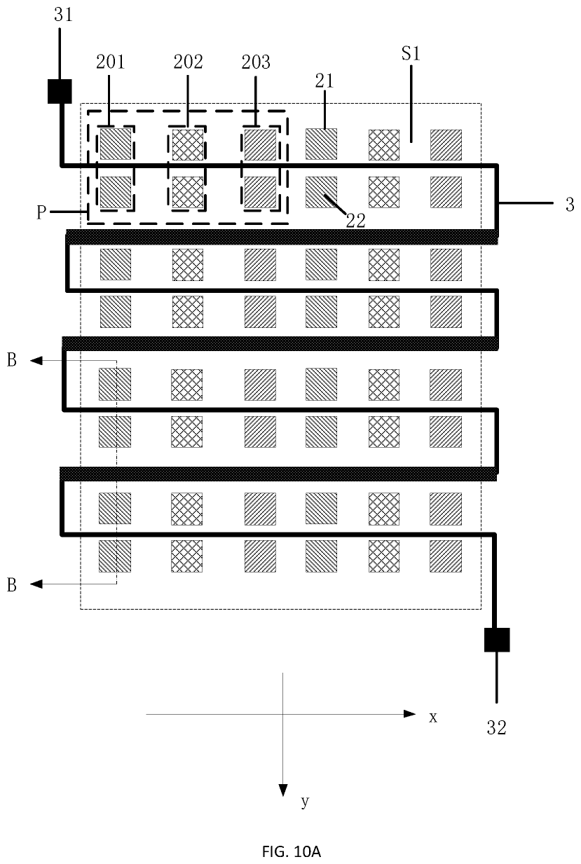

FIG. 9A is the sixth top view of the structure of the display substrate provided by an embodiment of the present disclosure. FIG. 9B is the seventh top view of the structure of the display substrate provided by an embodiment of the present disclosure. FIG. 9C is the eighth top view of the structure of the display substrate provided by an embodiment of the present disclosure.

In some embodiments, the wire 3 includes a first connecting portion and a second connecting portion that are relative to each other arranged on two sides of the pixel region S1 and extend in the first direction. The first connecting portion is connected with the input terminal, and the second connecting portion is connected with the output terminal. The wire 3 further includes a plurality of separating portions that extend in the second direction and are arranged in the first direction. One end of each separating portion is connected to the first connecting portion, and the other end of each separating portion is connected to the second connecting portion. Each separating portion passes through the pixel units that are on the same row in the second direction so that the first and second sub-pixels within each pixel unit are on both sides of the wire. Because each separating portion is connected in parallel with each other through the first connecting portion and the second connecting portion, it is conducive to reducing the internal resistance of the wire 3, and reducing the voltage between the input terminal 31 and the output terminal 32 of the wire 3 when the wire is energized. In the specific embodiment, because the current flowing through the first connecting portion and the second connecting portion is greater than the current flowing through each separating portion, the first connecting portion and the second connecting portion can be arranged to have a line width larger than a line width of each separating portion, so as to improve the current load capacity of the first connecting portion and the second connecting portion.

For example, as shown in FIG. 9A, a plurality of pixel units of the display substrate include a plurality of first pixel units 201, a plurality of second units 202 and a plurality of third pixel units 203. A first pixel unit 201, a second pixel unit 202 and a third pixel unit 203 arranged next to each other form a pixel group P. The first pixel unit 201 can be used for emitting green rays, the second pixel units 202 can be used for emitting red rays, and the third pixel units 203 can be used for emitting blue rays, so that the display of color images is realized. Specifically, a plurality of first pixel units 201, a plurality of second units 202 and a plurality of third pixel units 203 can be set according to the arrangement of RGB. Specifically, as shown in FIG. 9A, the first pixel unit 201, the second pixel unit 202, and the third pixel unit 203 in the same pixel group P are arranged side by side along the second direction y. A plurality of pixel groups P in the pixel region S1 are arranged in an array along the first direction x and the second direction y, respectively. The first direction x and the second direction y cross. As shown in FIG. 9A, the first connecting portion 33 of the wire 3 is arranged on the first side of pixel region S1, one end of the first connecting portion 33 is connected to the input terminal 31 of the wire 3, and the other end of the first connecting portion 33 extends along the first direction x. The second connecting portion 34 of the wire 3 is arranged on the second side opposite to the first side, of the pixel region S1, one end of the second connecting portion 34 is connected to the output terminal 32 of the wire 3, and the other end of the second connecting portion 34 extends along the first direction x. The wire 3 also includes a plurality of separating portions 35 that extend along the second direction y and are arranged along the first direction x. As shown in FIG. 9A, one end of each separating portion 35 is connected with the first connecting portion 33, and the other end of each separating portion 35 is connected with the second connecting portion 34. Each separating portion 35 passes through the pixel units located in the same row on the second direction y, so that the first sub-pixel 21 and the second sub-pixel 22 in the pixel unit are positioned on both sides of the wire.

In the specific embodiment, the first connecting portion 33 and the second connecting portion 34 of the wire 3 may also extend along the second direction y, the separating portions 35 extend along the first direction x, and each separating portions 35 passes through the pixel units located in the same column on the first direction x, so that the first sub-pixel 21 and the second sub-pixel 22 in each pixel unit are positioned at both sides of the wire 3. No limitation is made here.

As shown in FIG. 9B, the plurality of pixel units of the display substrate include a plurality of first pixel units 201, a plurality of second units 202 and a plurality of third pixel units 203. A first pixel unit 201, a second pixel unit 202 and a third pixel unit 203 arranged next to each other form a pixel group P. The first pixel units 201 can be used for emitting green rays, the second pixel units 202 can be used for emitting red rays, and the third pixel units 203 can be used for emitting blue rays, so that the display of color images is realized. Specifically, a plurality of first pixel units 201, a plurality of second units 202, and a plurality of third pixel units 203 can be set according to the arrangement of S-Stripe. Specifically, as shown in FIG. 9B, the first pixel unit 201 and the second pixel unit 202 in the same pixel group P are arranged side by side on the same side of the third pixel unit 203 along the second direction y, and a plurality of pixel groups P in the pixel region S1 are arranged in an array along the first direction x and the second direction y, respectively. The first direction x and the second direction y cross. As shown in FIG. 9B, the first connecting portion 33 of the wire 3 is arranged on the first side of the pixel region S1, one end of the first connecting portion 33 is connected to the input terminal 31 of the wire 3, and the other end of the first connecting portion 33 extends along the first direction x. The second connecting portion 34 of the wire 3 is arranged on the second side opposite to the first side, of the pixel region S1, one end of the second connecting portion 34 is connected to the output terminal 32 of the wire 3, and the other end of the second connecting portion 34 extends along the first direction x. The wire 3 also includes a plurality of separating portions 35 that extend along the second direction y and are arranged along the first direction x. One end of each separating portion 35 is connected with the first connecting portion 33, and the other end of each separating portion 35 is connected with the second connecting portion 34. As shown in FIG. 9B, in a plurality of pixel groups P arranged in the same column along the second direction y, the first pixel units 201 and the second pixel units 202 arranged on the same side of the third pixel units 203 are arranged in a row along the second direction y, and the third pixel units 203 in the plurality of pixel groups P are arranged in a row along the second direction y. A part of separating portions 35 pass through the first pixel units 201 and the second pixel units 202 in the same column on the second direction y, and the remaining part of separating portion 35 pass through the first third pixel units 203 in the same column on the second direction y, so that in all pixel units in the pixel region S1, the first sub-pixel 21 and the second sub-pixel 22 are located on both sides of the wire 3.

As shown in FIG. 9C, a plurality of pixel units of the display substrate include a plurality of first pixel units 201, a plurality of second units 202 and a plurality of third pixel units 203. A first pixel unit 201, a second pixel unit 202 and a third pixel unit 203 arranged next to each other form a pixel group P. The first pixel units 201 can be used for emitting green rays, the second pixel units 202 can be used for emitting red rays, and the third pixel units 203 can be used for emitting blue rays, so that the display of color images is realized. Specifically, a plurality of first pixel units 201, a plurality of second units 202, and a plurality of third pixel units 203 can be set according to the arrangement of S-Stripe. Specifically, as shown in FIG. 9C, the first pixel unit 201 and the second pixel unit 202 in the same pixel group P are arranged side by side on the same side of the third pixel unit 203 along the first direction x, and a plurality of pixel groups P in the pixel region S1 are arranged in an array along the first direction x and the second direction y respectively. The first direction x and the second direction y cross. As shown in FIG. 9C, the first connecting portion 33 of the wire 3 is arranged on the first side of the pixel region S1, one end of the first connecting portion 33 is connected to the input terminal 31 of the wire 3, and the other end of the first connecting portion 33 extends along the first direction x, the second connecting portion 34 of the wire 3 is arranged on the second side opposite to the first side, of the pixel region S1, one end of the second connecting portion 34 is connected to the output terminal 32 of the wire 3, and the other end of the second connecting portion 34 extends along the first direction x. The wire 3 also includes a plurality of separating portions 35 that extend along the second direction y and are arranged along the first direction x. One end of each separating portion 35 is connected with the first connecting portion 33, and the other end of each separating portion 35 is connected with the second connecting portion 34. As shown in FIG. 9C, in a pixel group P, the first pixel unit 201 and the second pixel unit 202 are arranged side by side on the same side of the third pixel unit 203 along the first direction x, and each separating portion 35 includes a first branch 351 passing through the first pixel unit 201 and a second branch 352 passing through the second pixel unit 202 respectively. The first branch 331 and the second branch 332 after passing through the first pixel unit 201 and the second pixel unit 202 respectively, merge a wire to passing through the third pixel unit 203, so that the first sub-pixel 21 and the second sub-pixel 22 are located on both sides of the wire 3 in all pixel units in the pixel region S1.

Referring to FIGS. 9A, 9B, the wire 3 is easier to design, to ablate multiple columns or rows simultaneously. Referring to the mode of FIG. 9C, it can be seen that the mode of FIG. 9C combines the modes of FIGS. 8C and 9A, and reflects the advantages of FIGS. 8C and 9A. For example, multiple rows can be ablated synchronously, and at the same time, a certain degree of separation between adjacent pixel units 2 can be formed.

In the embodiment shown in FIG. 9A~FIG. 9C, the first connecting portion 33 and the second connecting portion 34 may both be arranged outside the pixel region S1. In some embodiments, the first connecting portion 33 and the second connecting portion 34 may both be arranged within the pixel region S1. In some embodiments, one of the first connecting portion 33 and the second connecting portion 34 may be arranged within the pixel region S1 and the other may be arranged outside the pixel region S1, and is not limited herein.

In the embodiments shown in FIG. 9A~FIG. 9C, the arrangement of the wire 3 in the embodiment of the present disclosure is illustrated with the pixel units arranged in the RGB mode and the S-Stripe mode as examples, respectively. In the specific implementation, the arrangement of the pixel units is not limited to the RGB mode or the S-Stripe method. For example, the pixel units can also be set according to the PenTile arrangement, the diamond arrangement, the Delta arrangement, the Triangular PenTile arrangement, and so on. The specific setting modes of the above-mentioned various arrangements can refer to the related art, and will not be repeated here. When the pixel units are arranged according to any of the above-mentioned arrangements, the wire 3 can be arranged to include a first connecting portion, a second connecting portion, a plurality of separating portions, one end of each separating part in the plurality of separating portions is connected with the first connecting portion, and the other end is connected with the second connecting portion, so that the first sub-pixels 21 and the second sub-pixels 22 in each pixel unit 2 are positioned on both sides of the wire 3. The specific arrangement can refer to the embodiment shown in FIG. 9A~FIG. 9C, it will not be repeated here.

In the embodiment shown in FIG. 9A~FIG. 9C, a plurality of pixel units in the display substrate including a plurality of first pixel units 201, a plurality of second units 202 and a plurality of third pixel units 203 are used as an example to illustrate. In actual implementation, a plurality of pixel units in the display substrate may include more or less kinds of pixel units. For example, a plurality of pixel units in the display substrate can be pixel units that emit rays of the same color, so as to realize monochrome display, and no limitation is made herein.

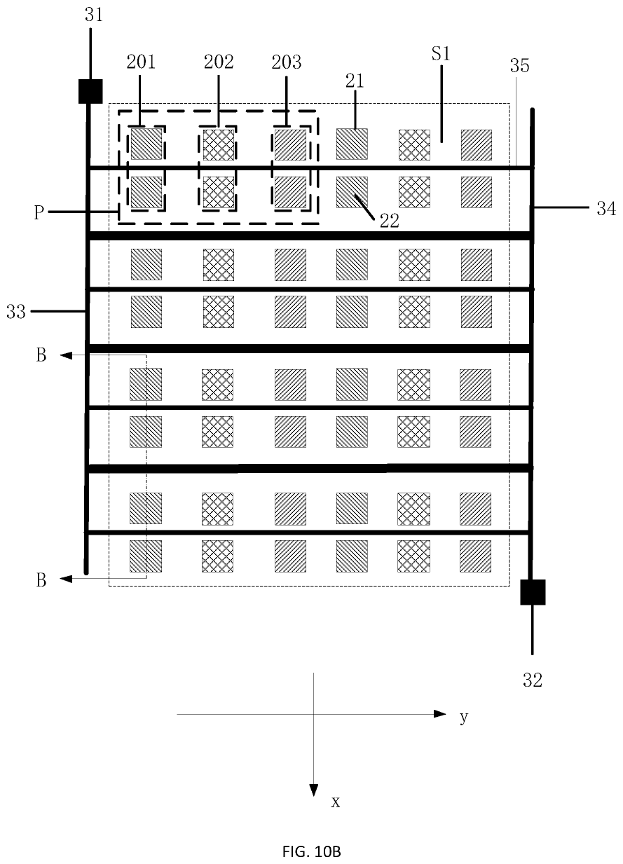

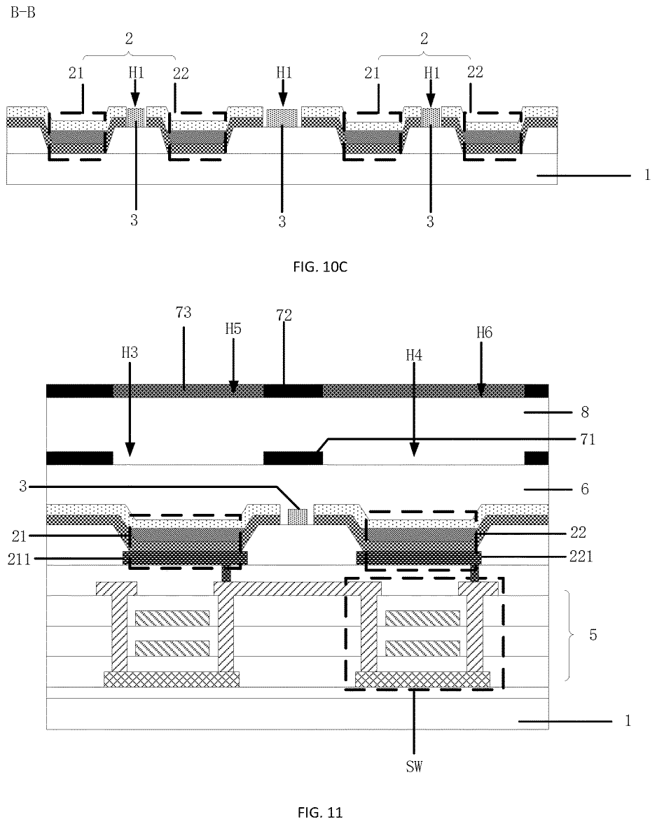

FIG. 10A is the ninth top view of the structure of the display substrate provided by an embodiment of the present disclosure. FIG. 10B is the tenth top view of the structure of the display substrate provided by an embodiment of the present disclosure. FIG. 10C is the fifth the cross-sectional view of the structure of the display substrate provided by an embodiment of the present disclosure.

In the embodiment of the present disclosure, because the common film layer 200 is made on the whole surface through the OM, a part of the film layers of the common film layer 200 are also located between the adjacent two pixel units 2 and connect the adjacent two pixel units 2. With the improvement of the resolution of the display substrate, the distance between adjacent pixel units 2 decreases, and the risk of current crosstalk due to the common film layer 200 between adjacent pixel units 2 increases. In some embodiments, at least part of the adjacent pixel units 2 can also be arranged on both sides of the wire 3, and the common film layer connecting the adjacent pixel units 2 is broken through the heating of the wire 3, so that the risk of current crosstalk between the adjacent pixel units 2 is reduced.

In some embodiments, as shown in FIG. 10A, the wire 3 passes through multiple pixel units located in the same row and passes through the middle region of two adjacent row of pixel units. As shown in FIG. 10C, FIG. 10C is a cross-sectional view of FIG. 10A along cross-sectional lines B-B, the common film layer has a first opening H1 formed by ablation of the wires 3 at positions corresponding to the wire 3 located between adjacent pixel units 2.

In some embodiments, as shown in FIG. 10B, the separating portion 35 passes through a plurality of pixel units located in the same row and passes through a middle region located in two adjacent rows of pixel units. As shown in FIG. 10C, FIG. 10C is a cross-sectional view of FIG. 10A along cross-sectional lines B-B, the common film layer has a first opening H1 formed by ablation of the wire 3 at positions corresponding to the wire 3 located between adjacent pixel units 2.

In the specific embodiment, in the embodiments shown in FIG. 8A~FIG. 8C and FIG. 9A~FIG. 9C, the wire 3 can be set with reference to the setting mode of the wire 3 in the embodiments shown in FIG. 10A and FIG. 10B, and is not repeated herein.

In some embodiments, as shown in FIG. 10A~FIG. 10C, the width of the first opening H1 corresponding to the position of the wire 3 between the first sub-pixel 21 and the second sub-pixel 22 in the same pixel unit 2 is smaller than the width of the first opening H1 corresponding to the position of the wire 3 between the pixel units 2 of adjacent rows. Similarly, the width of the wire 3 between the first sub-pixel 21 and the second sub-pixel 22 in the same pixel unit 2 is less than the width of the wire 3 between the pixel units 2 of adjacent rows. For example, as shown in FIG. 10B, the width of the separating portion 35 passing through the same row of pixel units is less than the width of the separating portion 35 between the pixel units 2 of adjacent rows. In general, the spacing between the pixel units 2 of adjacent rows is usually greater than the spacing between the first sub-pixel 21 and the second sub-pixel 22 in the same pixel unit. This design is conducive to expanding the spacing of the first opening H1 of the common film layer disconnection in the middle region of the adjacent two rows of pixel units, and further reduces the crosstalk of the adjacent row of pixel units.

FIG. 11 is the sixth cross-sectional of the structure of the display substrate provided by an embodiment of the present disclosure.

In some embodiments, the display substrate further includes a drive circuit layer 5. As shown in FIG. 11, the drive circuit layer 5 is located between the substrate 1 and the pixel units. The drive circuit layer 5 includes a plurality of pixel circuits, and the pixel circuits are electrically connected with the pixel units and are used for driving the pixel units to emit light and carry out image display.

In some embodiments, in the same pixel unit, a first sub-pixel 21 is separately connected to a pixel circuit, a second sub-pixel 22 is separately connected to a pixel circuit, and the first sub-pixel 21 and the second sub-pixel 22 can be driven separately through the pixel circuits that are connected separately.

In some embodiments, in the same pixel unit, the first sub-pixel 21 and the second sub-pixel 22 are connected to the same pixel circuit, so that the number of pixel circuits arranged in the drive circuit layer 5 can be reduced, and the difficulty of manufacture is reduced. In specific implementation, the pixel circuit can adopt a thin film transistor (TFT) pixel circuit. A TFT pixel circuit includes multiple thin-film transistors, such as two thin-film transistors and one capacitor are included in the most basic 2T1C pixel circuit. The TFT pixel circuits can also include a larger number of thin-film transistors to form 6T1C pixel circuits, 7T1C pixel circuits, etc., to achieve finer control effects. The specific structure of TFT pixel circuit can refer to the related art, and will not be repeated here. The drive circuit layer 5 also includes a plurality of switching thin-film transistor SWs. In the specific embodiment, the output terminal of the pixel circuit is connected with the first electrode 211 of the first sub-pixel 21, the drain of the switching thin-film transistor SW is connected to the second electrode 221 of the second sub-pixel 22, and the source of the switching thin-film transistor SW is connected to the first electrode 211 of the first sub-pixel 21. When the switching TFT SW is turned off, the drive signal output by the pixel circuit only drives the first sub-pixel 21 to light up for image display. When the switching TFT SW is turned on, the drive signal output by the pixel circuit can simultaneously drive the first sub-pixel 21 and the second sub-pixel 22 to light up for image display, so that the switching between the anti-peeping mode and the sharing mode can be realized by turning on and turning off the switching TFT SW.

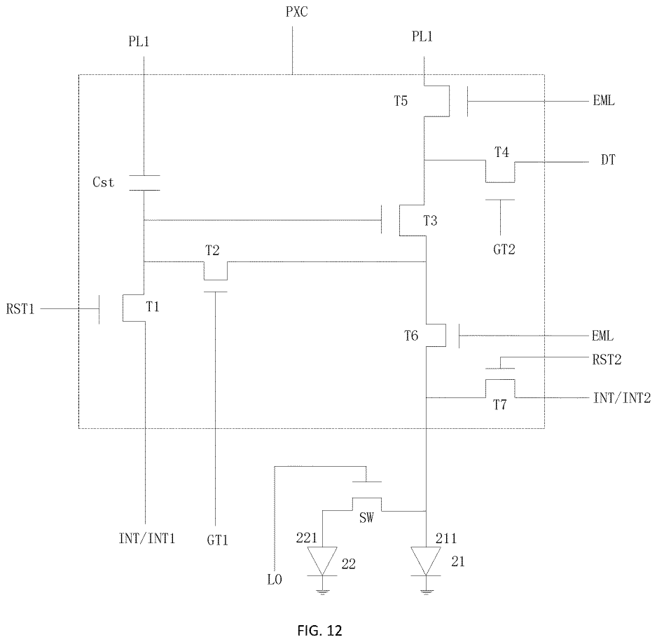

FIG. 12 is the equivalent circuit diagram of the pixel circuit provided by an embodiment of the present disclosure.

For example, as shown in FIG. 12, the first sub-pixel 21 and the second sub-pixel 22 share the same pixel circuit PXC. For example, as shown in FIG. 12, in the display substrate provided in the embodiment of the present disclosure, the drive circuit layer 5 includes a switching thin-film transistor SW. The pixel circuit PXC is connected to the first sub-pixel 21, and the pixel circuit PXC is connected to the second sub-pixel 22 through the switching thin-film transistor SW. For example, as shown in FIG. 12, the pixel circuit PXC is connected to the first electrode 211 of the first sub-pixel 21, and the pixel circuit PXC is connected to the second electrode 221 of the second sub-pixel 22 through the switching thin-film transistor SW. In the display substrate provided in the embodiment of the present disclosure, the specific process of switching between the anti-peeping mode and the sharing mode is realized by switching the thin-film transistor SW as follows: when the switching thin-film transistor SW is turned off, the pixel circuit PXC is disconnected from the second sub-pixel 22, and the driving signal output by the pixel circuit PXC only drives the first sub-pixel 21 to light up for image display; when the switching TFT SW is turned on, the pixel circuit PXC communicates with the second sub-pixel 22, and the driving signal output by the pixel circuit PXC can drive the first sub-pixel 21 and the second sub-pixel 22 to light up at the same time for image display.

As shown in FIG. 12, the pixel circuit PXC includes six switching thin-film transistors (T1-T2, T4-T7), a drive thin-film transistor T3, and a storage capacitor Cst. The six switching TFTs are the data write TFT T4, the threshold compensation TFT T2, the luminescence control TFT T5, the luminescence control TFT T6, the reset TFT T1, and the reset TFT T7.

As shown in FIG. 12, the gate of the luminescence control TFT T5 and the gate of the luminescence control TFT T6 are connected to the luminescence control signal line EML. The gate of the data write thin-film transistor T4 is connected to the scan line GT2. The gate of the reset TFT T7 is connected to the reset control signal line RST2. The gate of the threshold-compensated TFT T2 is connected to the gate line GT1. The gate of the reset TFT T1 is connected to the reset control signal line RST1.

As shown in FIG. 12, one end of the storage capacitor Cst is connected to the gate of the drive TFT T3, the other end of the storage capacitor Cst is connected to the power line PL1. One end of the luminescence control TFT T5 is connected to the drive TFT T3, and the other end of the luminescence control TFT T5 is connected to the power line PL1.

The embodiment shown in FIG. 12 is illustrated with a pixel circuit of 7T1C as an example. However, the embodiment of the present disclosure does not limit the structure of the pixel circuit, and a suitable pixel circuit can be selected according to the need, that is, the setting of the thin-film transistor and the setting of the capacitance in the pixel circuit can be determined as needed.

In the embodiment of the present disclosure, the display substrate further includes a thin film encapsulation, TFE layer 6. The TFE layer 6 is positioned on a side away from the substrate 1, of the pixel unit, and is used for protecting the pixel unit and avoiding water and oxygen from invading into the film layer of the pixel unit, causing the material to oxidize and fail to carry out normal lighting. In specific embodiment, the TFE layer 6 may include at least one film layer. For example, the TFE layer 6 can be a sandwich structure including a first inorganic layer, an organic layer and a second inorganic layer stacked in a direction away from the substrate 1. For specific arrangement, refer to the related art, which is not limited here.

In the embodiment of the disclosure, the display substrate further includes a first black matrix layer 71, an insulating material layer 8 and a second black matrix layer 72 stacked in a direction away from the substrate 1. The insulating material layer 8 can be made of organic insulating material or inorganic insulating material. The first black matrix layer 71 and the second black matrix layer 72 can be made of black shading material, and there is no restriction here.

In specific implementation, the first black matrix layer 71 may be arranged on a side away from the substrate 1, of the TFE layer 6. The first black matrix layer 71 is provided with a third opening H3 corresponding to the first sub-pixel 21 and a fourth opening H4 corresponding to the second sub-pixel 22. The second black matrix layer 72 is provided with a fifth opening H5 corresponding to the first sub-pixel 21 and a sixth opening H6 corresponding to the second sub-pixel 22. The orthographic projection of the first sub-pixel 21 on the substrate 1 overlaps at least partially with the orthographic projection of the third opening H3 on the substrate 1. The orthotropic projection of the first sub-pixel 21 on the substrate 1 overlaps at least partially with the orthotropic projection of the fifth opening H5 on the substrate 1. The orthotropic projection of the second sub-pixel 22 on the substrate 1 at least partially overlaps with the orthotropic projection of the fourth opening H4 on the substrate 1, and the orthographic projection of the second sub-pixel 22 on the substrate 1 overlaps at least partially with the orthographic projection of the sixth opening H6 on the substrate 1. The third opening H3 and the fifth opening H5 are used for transmitting the rays emitted by the first sub-pixel 21, and the fourth openings H4 and the sixth openings H6 are used for transmitting the rays emitted by the second sub-pixels 22.

In the specific embodiment, the area of the orthographic projection of the fifth opening H5 on the substrate 1 can be set to be less than or equal to the area of the orthographic projection of the third opening H3 on the substrate 1, thereby being conducive to blocking the large-angle rays emitted by the first sub-pixel 21 through the first black matrix layer 71 and the second black matrix layer 72, and reducing the viewing angle of the display in the anti-peeping mode, and improving the anti-peeping effect. The area of the orthographic projection of the sixth opening H6 on the substrate 1 can be set to be greater than or equal to the area of the orthographic projection of the fourth opening H4 on the substrate 1, thereby being conducive to the diffusion of the light emitted by the second sub-pixel 22, increasing the viewing angle of the display in the sharing mode, and conducive to the sharing of the display screen.

In the specific embodiment, the area of the orthographic projection of the fourth opening H4 on the substrate 1 and the area of the orthographic projection of the sixth opening H6 on the substrate 1 can be set to be greater than the area of the orthographic projection of the third opening H3 on the substrate 1, and greater than the area of the orthographic projection of the fifth opening H5 on the substrate 1, thereby being conducive to reducing the viewing angle of the display in the anti-peeping mode, improving the anti-peeping effect and increasing the viewing angle of the sharing mode display, and is conducive to the sharing of the display screen.

In some embodiments, as shown in FIG. 11, the orthographic projection of wire 3 on substrate 1 is at least partially within the orthographic projection of the first black matrix layer 71 on substrate 1. The wire 3 can be partially blocked by the first black matrix layer 71, so that the light reflected by the wire 3 can be reduced, and the display effect is improved. In addition, it is possible to reduce the occupation of the wire 3 on the pixel setting area, which is conducive to improving the resolution. For example, the orthographic projection of wire 3 on substrate 1 can be set to fall into the orthographic projection of the first black matrix layer 71 on substrate 1, and no limitation is made here.

In some embodiments, as shown in FIG. 11, the orthotropic projection of wire 3 on substrate 1 is at least partially within the orthographic projection of the second black matrix layer 72 on substrate 1. The wire 3 can be partially blocked by the second black matrix layer 72, so that the light reflected by the wire 3 can be reduced and the display effect is improved. In addition, it is possible to reduce the occupation of the wire 3 on the pixel setting area, which is conducive to improving the resolution. For example, the orthographic projection of wire 3 on substrate 1 can be set to fall into the orthographic projection of the second black matrix layer 72 on substrate 1, and no limitation is made here.

In some embodiments, a part of the orthographic projection of the wire 3 on the substrate 1 can fall into the orthographic projection of the first black matrix layer 71 on the substrate 1, and the remaining part of the orthographic projection of the wire 3 falls into the orthographic projection of the second black matrix layer 72 on the substrate 1, so that the light reflected by the wire 3 can be blocked simultaneously by the first black matrix layer 71 and the second black matrix layer 72, and the display effect is improved. In addition, it is possible to reduce the occupation of the wire 3 on the pixel setting area, which is conducive to improving the resolution. For example, the orthographic projection of the first black matrix layer 71 on the substrate 1 and the orthographic projection of the second black matrix layer 72 on the substrate 1 only partially overlap. The first black matrix layer 71 can partially block the wire 3, and the part of the wire 3 that is not blocked by the first black matrix layer 71 can be blocked by the part of the second black matrix layer 72 that does not overlap with the first black matrix layer 71. No limitation is made here.

In some embodiments, the wire 3 may be made of a non-transparent conductive material. The wire 3 is located between the first sub-pixel 21 and the second sub-pixel 22 in the same pixel unit, or is arranged between the two adjacent pixel units, so that the wire 3 made of a non-transparent conductive material, for example, in the anti-peeping mode, can block the light that the first sub-pixel 21 emits to the area where the second sub-pixel 22 is located, avoid ray crosstalk, and improve the anti-peeping effect. For example, in the sharing mode, the wire 3 can block the rays emitted by pixel units to adjacent pixel units, reduce the crosstalk between the rays emitted by different pixel units, and improve the display effect. For example, wire 3 can be made of black light-blocking material, which is not limited here.

In some embodiments, the display substrate further includes a filter layer 73. In the specific embodiment, as shown in FIG. 11, the filter layer 73 can be all arranged in the fifth opening H5 and the sixth opening H6 of the second black matrix layer 72. In some embodiments, the filter layer 73 may be all arranged in the third opening H3 and the fourth opening H4 of the first black matrix layer 71. In some embodiments, the filter layer 73 may be arranged in the third opening H3, the fourth opening H4, the fifth opening H5 and the sixth opening H6 at the same time, and is not limited herein. The filter layer 73 may include a plurality of light filters, one of which corresponds to the first sub-pixel 21 or the second sub-pixel 22. The light filter is used for transmitting the light of which the color is the same as the color of light emitted by the corresponding first sub-pixel 21 or the second sub-pixel 22, and filtering out the light, of which the is different from the color of light emitted by the corresponding first sub-pixel 21 or the second sub-pixel 22, so that the display effect is optimized.

In order to clearly reflect the main points of the display substrate provided by the embodiment of the present disclosure, a part of the film layers structure of the display substrate are omitted in the accompanying drawings of the embodiment of the present disclosure. The display substrate provided by the embodiment of the present disclosure also includes other film layer structures not mentioned in the present disclosure that are necessary to achieve specific functions. These film layer structures have been widely existing in the related art, and the relevant technologies may be referred to in the specific implementation, and will not be repeated herein.

Some embodiments of the disclosure also provide a display device. The display device provided by the embodiments of the disclosure includes a display substrate provided by any one of the above embodiments. In the specific embodiment, the display device provided in the embodiments of the present disclosure has the same or similar technical effect as any of the display substrate in the above embodiments, and will not be repeated herein.

The display device provided by the embodiments of the present disclosure includes, but is not limited to, an OLED display device. The display devices provided by the embodiments may be televisions, mobile phones, tablet computers, laptop computers, smart watches, digital cameras, etc., using the display substrates provided in any of the above embodiments, and are not limited herein.

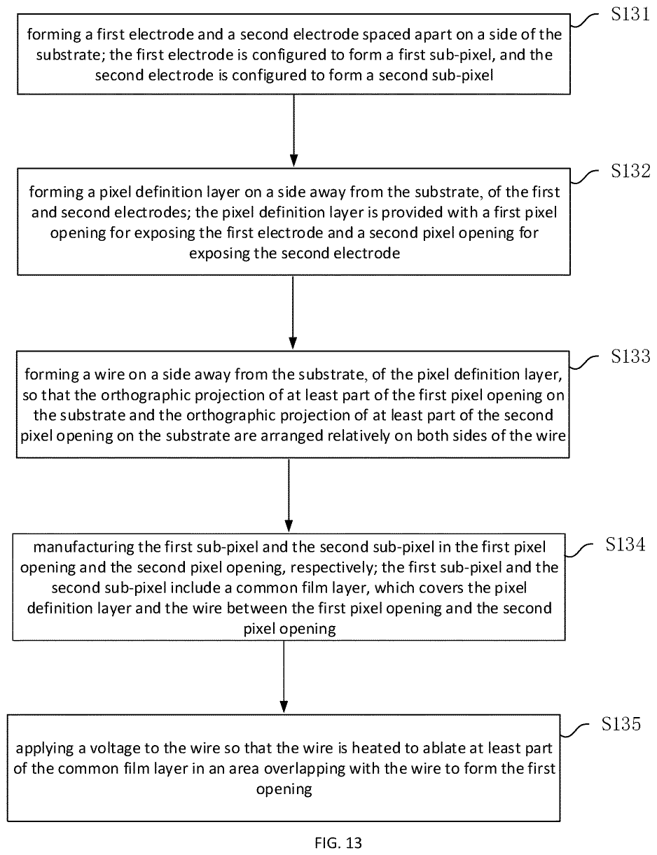

FIG. 13 is the first flow chart of the manufacturing method of the display substrate provided by an embodiment of the present disclosure.

The embodiment of the disclosure also provides a method for manufacturing a display substrate, as shown in FIG. 13, and the method for manufacturing the display substrate includes the following steps:
S131: forming a first electrode and a second electrode spaced apart on a side of the substrate; the first electrode is configured to form a first sub-pixel, and the second electrode is configured to form a second sub-pixel;
S132: forming a pixel definition layer on a side away from the substrate, of the first and second electrodes; the pixel definition layer is provided with a first pixel opening for exposing the first electrode and a second pixel opening for exposing the second electrode;
S133: forming a wire on a side away from the substrate, of the pixel definition layer, so that the orthographic projection of at least part of the first pixel opening on the substrate and the orthographic projection of at least part of the second pixel opening on the substrate are arranged relatively on both sides of the wire;
S134: manufacturing the first sub-pixel and the second sub-pixel in the first pixel opening and the second pixel opening, respectively; the first sub-pixel and the second sub-pixel include a common film layer, which covers the pixel definition layer and the wire between the first pixel opening and the second pixel opening;
S135: applying a voltage to the wire so that the wire is heated to ablate at least part of the common film layer in an area overlapping with the wire to form the first opening.

The manufacturing method of the display substrate provided by the embodiments of the present disclosure is to make a wire in the area between at least a part of the first pixel opening and at least a part of the second pixel opening on the pixel definition layer before forming a common film layer of the first sub-pixel and the second sub-pixel. The first pixel opening and the second pixel opening on both sides of the wire can be used to make the first sub-pixel and the second sub-pixel in the same pixel unit, respectively. Then, a common film layer is formed on the side away from the pixel definition layer, of the wire, and at least part of film layer of the common film layer in contact with the wire are ablated by heating the wire, so that at least a part of the common film layer is broken at the corresponding position of the wire to form the first opening, so as to effectively reduce the risk of current crosstalk between the first sub-pixel and the second sub-pixel in the same pixel unit. For example, in the anti-peeping mode, the anti-peeping effect can be improved. In addition, the manufacturing method of the display substrate provided by the embodiment of the present disclosure forms the wire on the side away from the substrate, of the pixel definition layer, so that an opening for exposing the wire can be avoided in the pixel definition layer, the process step is simplified, and the structural strength of the pixel definition layer is conducive to improving.

In the specific embodiment, the specific steps of the manufacturing method of the above-mentioned display substrate provided in the embodiment of the present disclosure may refer to the specific structure of the display substrate provided in the above-mentioned embodiment of the disclosure, and will not be repeated herein.

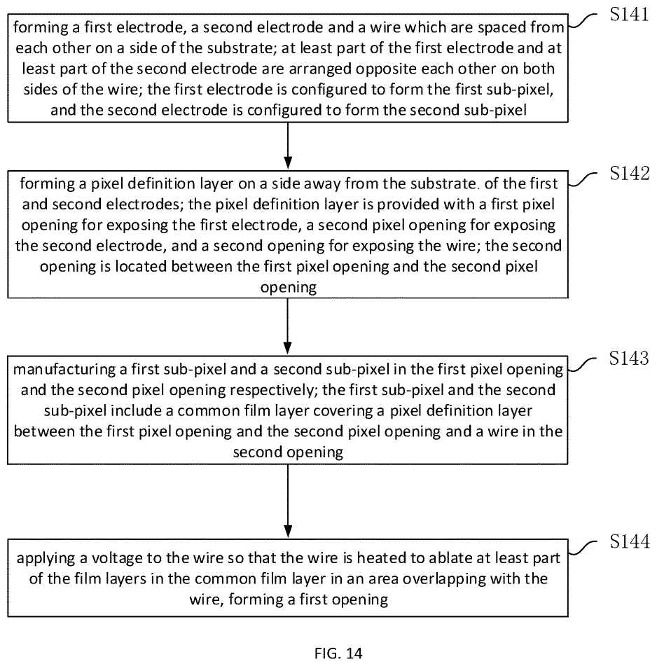

FIG. 14 is the second flow chart of the manufacturing method of the display substrate provided by the embodiments of the present disclosure.

Some embodiments of the disclosure also provide a method for manufacturing a display substrate, as shown in FIG. 14, and the method for manufacturing the display substrate includes the following steps:
S141: forming a first electrode, a second electrode and a wire which are spaced from each other on a side of the substrate; at least part of the first electrode and at least part of the second electrode are arranged opposite each other on both sides of the wire; the first electrode is configured to form the first sub-pixel, and the second electrode is configured to form the second sub-pixel;
S142: forming a pixel definition layer on a side away from the substrate. of the first and second electrodes; the pixel definition layer is provided with a first pixel opening for exposing the first electrode, a second pixel opening for exposing the second electrode, and a second opening for exposing the wire; the second opening is located between the first pixel opening and the second pixel opening;
S143: manufacturing a first sub-pixel and a second sub-pixel in the first pixel opening and the second pixel opening respectively; the first sub-pixel and the second sub-pixel include a common film layer covering a pixel definition layer between the first pixel opening and the second pixel opening and a wire in the second opening;
S144: applying a voltage to the wire so that the wire is heated to ablate at least part of the film layers in the common film layer in an area overlapping with the wire, forming a first opening.

The manufacturing method of the display substrate provided by the embodiments of the present disclosure is to make a wire in the area between at least part of the first electrode and at least part of the second electrode before forming a common film layer of the first sub-pixel and the second sub-pixel. The first electrode and the second electrode on both sides of the wire can be used to make the first sub-pixel and the second sub-pixel in the same pixel unit, respectively. Then a pixel definition layer is made on the side away from the substrate, of the wire, and is opened with a first pixel opening for exposing the first electrode, a second pixel opening for exposing the second electrode and a second opening for exposing the wire. Then a common film layer is formed on the side away from the substrate, of the pixel definition layer, so that the common film layer covers the pixel definition layer between the first pixel opening and the second pixel opening and the wire in the second opening, and ablate at least part of the common film layer in contact with the wire. At least a part of the common film layer is broken at the position corresponding to the wire to form the first opening, so as to effectively reduce the risk of current crosstalk between the first sub-pixel and the second sub-pixel in the same pixel unit. For example, in the anti-peeping mode, the anti-peeping effect can be improved. In addition, the manufacturing method of the display substrate provided by the embodiments of the present disclosure allows the wire and the first electrode and the second electrode to be made in the same conductive film layer, which is conducive to reducing the number of film layers of the display substrate and reducing the thickness of the display substrate.

In the specific embodiment, the specific steps of the manufacturing method of the above-mentioned display substrate provided by the embodiments of the present disclosure may refer to the specific structure of the display substrate provided in the above-mentioned embodiments of the disclosure, and will not be repeated herein.

Although preferred embodiments of the present disclosure have been described, a person skilled in the art may make additional changes and modifications to these embodiments once they have knowledge of the basic concept of inventive step. Therefore, the attached claims are intended to be construed to include the preferred embodiments and all changes and modifications that fall within the scope of this disclosure.

Obviously, a person skilled in the art may make various alterations and variations to the present disclosure without departing from the spirit and scope of the present disclosure. Thus, if such modifications and variants of the present disclosure fall within the scope of the claims of the present disclosure and its equivalents, the present disclosure is also intended to include such modifications and variants.

1. A display substrate, comprising:
a substrate;
a plurality of pixel units located on the substrate; wherein each of the pixel units comprises a first sub-pixel and a second sub-pixel; the first sub-pixel and the second sub-pixel comprise a common film layer;
a wire, wherein for at least a part of the pixel units, an orthographic projection of the first sub-pixel on the substrate and an orthographic projection of the second sub-pixel on the substrate, are relatively arranged on both sides of the wire; at least a part of the common film layer is broken in an area overlapping with the wire and is spaced apart from the wire to form a first opening.

2. The display substrate of claim 1, further comprising:
a pixel definition layer located on a side of the substrate; wherein the pixel definition layer is provided with a first pixel opening and a second pixel opening; the first pixel opening and the second pixel opening pass through the pixel definition layer along a thickness direction of the pixel definition layer; the common film layer is located on a side away from the substrate, of the pixel definition layer, and is partly located between the first pixel opening and the second pixel opening;
the first sub-pixel and the second sub-pixel are separated by a part of the pixel definition layer located between the first pixel opening and the second pixel opening; for each of the pixel units, an orthographic projection of the first pixel opening on the substrate and an orthographic projection of the second pixel opening on the substrate are located on both sides of an orthotropic projection of the wire on the substrate.

3. The display substrate of claim 2, wherein the wire is located on the side away from the substrate, of the pixel defining layer.

4. The display substrate of claim 3, wherein the wire is located between the common film layer and the pixel definition layer.

5. The display substrate of claim 2, wherein the wire is located on a side away from the common film layer, of the pixel definition layer;
the pixel definition layer is further provided with a second opening; the second opening passes through the pixel definition layer along the thickness direction of the pixel definition layer, and exposes the wire; at least a part of the common film layer is broken at a position of the second opening to form the first opening.

6. The display substrate of claim 5, further comprising a first electrode and a second electrode located between the pixel definition layer and the substrate; wherein the first electrode and the second electrode are spaced apart; the first electrode is used for forming the first sub-pixel, and the second electrode is used for forming the second sub-pixel;
for each of the pixel units, an orthotropic projection of the first electrode on the substrate and an orthographic projection of the second electrode on the substrate are located on both sides of the orthographic projection of the wire on the substrate.

7. The display substrate of claim 6, wherein the wire is located in a conductive film layer same as a layer where the first electrode and the second electrode are located; the wire, the first electrode and the second electrode are separated by the pixel definition layer.

8. The display substrate of claim 1, further comprising a thermal insulation layer located on a side away from the common film layer, of the wire; an orthographic projection of the wire on the substrate is within an orthographic projection of the thermal insulation layer on the substrate.

9. The display substrate of claim 8, wherein the orthographic projection of the wire on the substrate and the orthographic projection of the thermal insulation layer on the substrate completely coincide.

10. The display substrate of claim 1, wherein the wire comprises an input terminal and an output terminal; the input terminal and the output terminal are used for loading a voltage on the wire to form a current.

11. The display substrate of claim 10, further comprising a pixel region and a non-pixel region; the pixel units are located within the pixel region; the input terminal and the output terminal of the wire are located within the non-pixel region.

12. The display substrate of claim 11, wherein the wire continuously passes through each of the pixel units within the pixel region, so that the first sub-pixel and the second sub-pixel in each of the pixel units are positioned on both sides of the wire.

13. The display substrate of claim 11, wherein the wire comprises a first connecting portion and a second connecting portion; the first connecting portion and the second connecting portion are relatively arranged on both sides of the pixel region and extend along a first direction; wherein the first connecting portion is connected with the input terminal, and the second connecting portion is connected with the output terminal;
the wire further comprises a plurality of separating portions extending in a second direction and arranging in the first direction; one end of each of the separating portions is connected with the first connecting portion, and the other end of each of the separating portions is connected with the second connecting portion; each of the separating portions passes through the pixel units located in a same row in the second direction, so that the first sub-pixel and the second sub-pixel in each of the pixel units are located on both sides of the wire.

14. The display substrate of claim 1 wherein a part of the common film layer is located between two adjacent pixel units;
at least a part of the pixel units are relatively arranged on both sides of the wire.

15. The display substrate of claim 1, wherein in a same pixel unit, a luminous color of the first sub-pixel is the same as a luminous color of the second sub-pixel.

16. The display substrate of claim 1, wherein the first sub-pixel and the second sub-pixel are organic light-emitting diodes;
the organic light-emitting diode comprises:
a first electrode layer located on a side of the substrate;
a first functional layer located on a side away from the substrate, of the first electrode layer; wherein the first functional layer comprises at least one film layer;
an organic light-emitting layer located on a side away from the first electrode layer, of the first functional layer;
a second functional layer located on a side away from the first functional layer, of the organic light-emitting layer; wherein the second functional layer comprises at least one film layer;
a second electrode layer located on a side away from the organic light-emitting layer, of the second functional layer;
the common film layer comprises at least one of the first functional layer, the second functional layer or the second electrode layer.

17. The display substrate of claim 16, wherein the first functional layer comprises a hole transport layer and a hole injection layer, the hole transport layer and the hole injection layer are stacked in a direction away from the organic light-emitting layer; the second functional layer comprises an electron transport layer and an electron injection layer, the electron transport layer and the electron injection layer are stacked in the direction away from the organic light-emitting layer.

18. A display device comprising the display substrate of claim 1.

19. A method for manufacturing a display substrate, comprising:
forming a first electrode and a second electrode spaced apart from each other on a side of a substrate; wherein the first electrode is used for forming a first sub-pixel, and the second electrode is used for forming a second sub-pixel;
forming a pixel definition layer on a side away from the substrate, of the first electrode and the second electrode; wherein the pixel definition layer is provided with a first pixel opening for exposing the first electrode and a second pixel opening for exposing the second electrode;
forming a wire on a side away from the substrate, of the pixel definition layer, so that an orthographic projection of at least a part of the first pixel opening on the substrate and an orthographic projection of at least a part of the second pixel opening on the substrate are relatively arranged on both sides of the wire;
manufacturing the first sub-pixel and the second sub-pixel respectively in the first pixel opening and the second pixel opening; wherein the first sub-pixel and the second sub-pixel comprise a common film layer, and the common film layer covers the pixel definition layer and the wire between the first pixel opening and the second pixel opening;
applying a voltage to the wire so that the wire is heated to ablate at least a part of the common film layer in an area overlapping with the wire to form the first opening.

20. A method for manufacturing a display substrate, comprising:
forming a first electrode, a second electrode and a wire which are spaced from each other on a side of a substrate; wherein at least a part of the first electrode and at least a part of the second electrode are relatively arranged on both sides of the wire; the first electrode is used for forming a first sub-pixel, and the second electrode is used for forming a second sub-pixel;
forming a pixel definition layer on a side away from the substrate, of the first electrode and the second electrode; wherein the pixel definition layer is provided with a first pixel opening for exposing the first electrode, a second pixel opening for exposing the second electrode and a second opening for exposing the wire; the second opening is between the first pixel opening and the second pixel opening;
manufacturing the first sub-pixel and the second sub-pixel respectively in the first pixel opening and the second pixel opening; wherein the first sub-pixel and the second sub-pixel comprise a common film layer, the common film layer covers the pixel definition layer between the first pixel opening and the second pixel opening, and the wire in the second opening;
applying a voltage to the wire so that the wire is heated to ablate at least a part of the common film layer in an area overlapping with the wire to form the first opening.
